(19) United States
(12) Patent Application Publication
(10) Pub. No.: US 2017/0200294 A1
(43) Pub. Date: Jul. 13, 2017

(54) CONTROL METHOD FOR INFORMATION TERMINAL AND INFORMATION TERMINAL

(71) Applicant: Panasonic Intellectual Property Management Co., Ltd., Osaka (JP)

(72) Inventor: JUN HIRANO, Osaka (JP)

(21) Appl. No.: 15/352,232

(22) Filed: Nov. 15, 2016

(30) Foreign Application Priority Data
Jan. 7, 2016 (JP) 2016-001985

(51) Int. Cl. G06T 11/20; G01J 1/42; G01P 5/00; G01K 13/02; G09G 5/14; G01R 22/06

(52) U.S. Cl. CPC G06T 11/206; G09G 5/14; G01R 22/061; G01P 5/00; G01K 13/028; G01J 1/4257

(57) ABSTRACT

In a method, an information terminal acquiring data from a storing device that stores data of first measured values associated with an operation of an energy-consuming apparatus installed at a facility, the first measured values being obtained by a first measuring device, upon receiving a request to indicate the first measured values for a plurality of days obtained by the first measuring device and associated with the operation of the energy-consuming apparatus, data of the first measured values for the plurality of days is acquired from the storing device, and a first display screen on which sizes of the first measured values are indicated, based on the data of the first measured values for the plurality of days, by different forms of indication in a first graph where a first axis represents dates and a second axis represents hours is displayed on the display.

### BACKGROUND

1. Technical Field

The present disclosure relates to display control for an information terminal.

2. Description of the Related Art

Japanese Unexamined Patent Application Publication No. 2011-180807 displays a long-term display unit that displays energy consumption in units of long time periods in a time-series manner. When a date button in the long-term display unit is clicked as a desired display position, the details of the energy consumption on the specified date are displayed as a short-term display unit that displays energy consumption in units of short time periods in a time-series manner on the same display screen as the long-term display unit.

### SUMMARY

However, analyzing measured values, such as energy consumption, with the display disclosed in Japanese Unexamined Patent Application Publication No. 2011-180807 may be considered not to be easy.

One non-limiting and exemplary embodiment provides a method for an information terminal for displaying on a display a display graph with which measured values may be analyzed easily.

In one general aspect, the techniques disclosed here feature a method for an information terminal, including: upon receiving a request to indicate first measured values for a plurality of days obtained by a first measuring device and associated with the operation of the energy-consuming apparatus installed at a facility, acquiring data of the first measured values for the plurality of days from the storing device; and displaying on a display of the information terminal a first display screen on which sizes of the first measured values are indicated, based on the data of the first measured values for the plurality of days, by different forms of indication in a first graph where a first axis represents dates and a second axis represents hours.

With the method for the information terminal according to the above aspect, a graph with which measured values may be analyzed easily may be displayed on a display.

It should be noted that general or specific embodiments may be implemented as a system, a method, an integrated circuit, a computer program, a storage medium, or any selective combination thereof.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1 is a configuration diagram of a facility that performs energy management according to an embodiment;

FIG. 2 is a system configuration diagram of an energy management system according to an embodiment;

FIG. 3 is a sequence diagram of a processing operation by the energy management system illustrated in FIG. 2;

FIG. 4 illustrates an example of a first display screen displayed on a display unit of an information terminal illustrated in FIG. 2;

FIG. 5 illustrates an example of a second display screen displayed on the display unit of the information terminal illustrated in FIG. 2;

FIG. 6 illustrates an example of a third display screen displayed on the display unit of the information terminal illustrated in FIG. 2;

FIG. 7 is a flowchart illustrating a processing operation of the information terminal illustrated in FIG. 2;

FIG. 8 is a transition diagram of display screens displayed on a display of the information terminal illustrated in FIG. 2;

FIG. 9 illustrates a modification of a first graph on the first display screen;

FIG. 10 illustrates another modification of the first graph on the first display screen;

FIG. 11 Illustrates still another modification of the first graph on the first display screen;

FIG. 12 illustrates an example of a graph used for an examination, the graph illustrating changes in measured values on an hour-by-hour basis; and

FIG. 13 illustrates an example of a graph used for an examination, the graph illustrating changes in measured values and details of the changes on a month-by-month basis.

### DETAILED DESCRIPTION

### <<Underlying Knowledge Forming Basis of Display Contents of Information Terminal According to the Present Disclosure>>

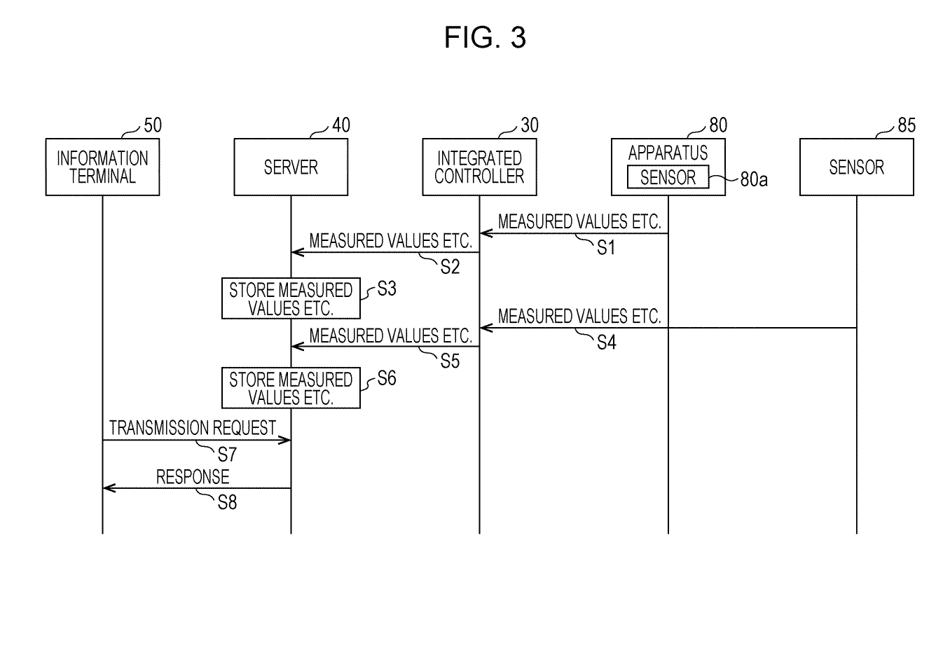

In Japanese Unexamined Patent Application Publication No. 2011-180807, as is clear from FIG. 3 of Japanese Unexamined Patent Application Publication No. 2011-180807, a long-term display unit is a graph in which the vertical axis represents the amount of power generated at a solar power generator and the horizontal axis represents two weeks on a day-to-day basis. A short-term display unit is a graph in which the vertical axis represents the amount of power generated at the solar power generator and the horizontal axis represents a specified date on an hour-by-hour basis.

Also in an energy management system in a store or the like, the operation conditions and power consumption of an apparatus may be managed or obtained by using a similar graph.

In management equipment and display equipment, to present a power-saving technique estimated based on a linkage operation of control target apparatuses to a user of the apparatuses, finding characteristics of individual time-series data, correlations between a plurality of apparatuses and sensors, and the like and analyzing the tendencies of energy consumption has been one of effective usages of an energy management system.

However, in the graphs disclosed in Japanese Unexamined Patent Application Publication No. 2011-180807, for example, in the case where the tendencies of power consumption of apparatuses installed in a store or the like, such as an air-conditioning apparatus, a lighting apparatus, and a cooling apparatus, are desired to be confirmed throughout a year, problems described below occur.

In analysis using an energy management system, it is necessary to compare time-series data for each sensor provided inside an apparatus for over a long period of time such as one year or longer and analyze characteristics. Therefore, a problem in which the number of target apparatuses and the length of the target period increase and an enormous length of time is required for analysis, a problem in which the entire tendency cannot be obtained only by referring to individual time-series data, a problem in which a determination based on the entire analysis fails to find characteristics, and other problems may occur. Furthermore, if a series of processes from analysis to execution of measures of improvement cannot function efficiently within limited resources (processing time for analysis, data amount, analysis staff, the amount of suggestion contents to be presented to an operator and executed, etc.), an oversight may occur in a suggestion for energy saving or the suggestion may not be used effectively.

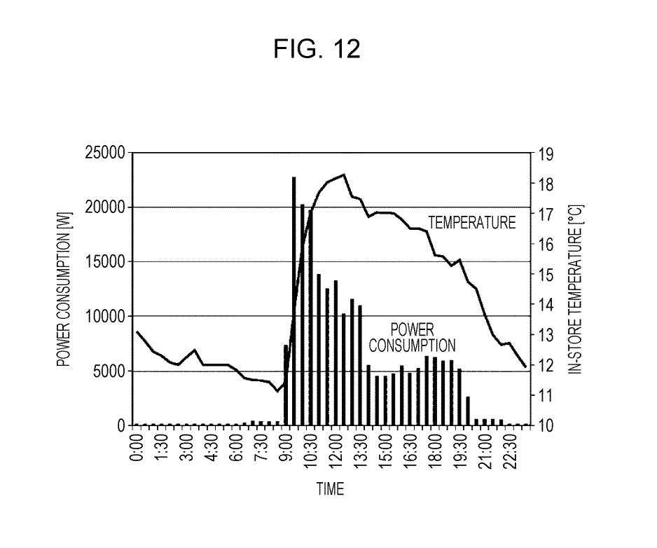

As an example in which the entire tendency cannot be obtained only by referring to individual time-series data, a graph representing hourly changes of a specific sensor is illustrated in FIG. 12. Such a graph is suitable for obtaining changes on an hour-by-hour basis. However, there is a limit to understanding the relationship between various sensors for a huge number of days. In this case, it is only possible to obtain the power consumption and the temperature of specific equipment for a single day.

For example, for confirmation of the power consumption or the like of, for example, an air-conditioning apparatus, a lighting apparatus, a cooling apparatus, or the like installed in a store, generating a graph in which a first axis represents one day and a second axis represents a power consumption or the like by citing the graphs illustrated in Japanese Unexamined Patent Application Publication No. 2011-180807 may be considered.

However, only with data for a single day, for example, a bird's-eye view of the entire tendency for one year cannot be obtained. In contrast, for example, in order to obtain a bird's-eye view of the whole year, 365 graphs need to be generated. In this case, a vast amount of data is to be confirmed. Moreover, individually confirming 365 graphs is not equal to overlooking the entire tendency of, for example, one year. Therefore, this may fail to obtain the entire tendency.

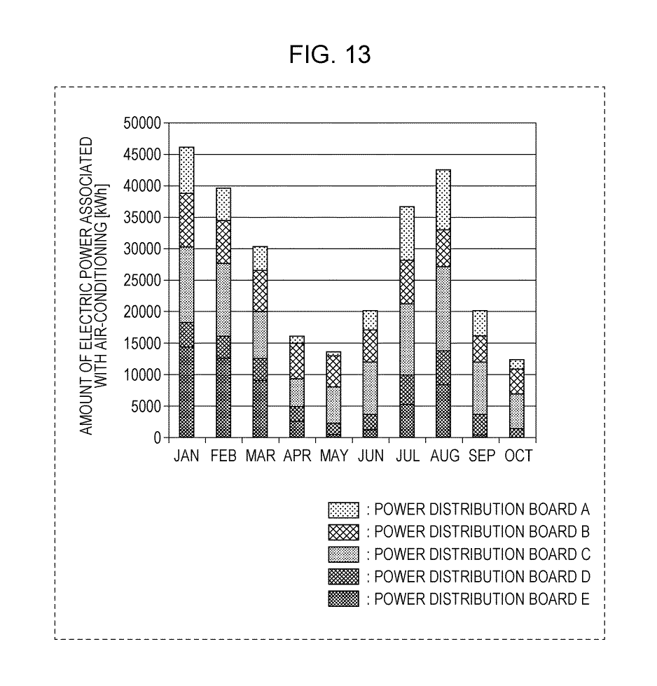

Furthermore, as an example in which a determination based on the entire analysis fails to find characteristics, a graph representing monthly usage of an electric power distribution panel is illustrated in FIG. 13. Although seasonal energy variations may be obtained by the entire monthly power usage, the details of individual electric power distribution panels, and the like, daily changes, existence/non-existence of false operation of a specific apparatus, and the like cannot be obtained.

Furthermore, for example, even if daily data is obtained, the graph represents the total amount of daily power consumption, and therefore, it is impossible to obtain which tendency is observed in which time zone of a day. For example, a confirmation as to whether failing to turn off the power at night caused waste of electric power during midnight, whether an amount of electric power larger than usual was consumed during daytime, or the like cannot be achieved. In this case, a cause for which countermeasures are to be taken may be missed.

Furthermore, for example, normality or abnormality of the power consumption or the like of an air-conditioning apparatus, a lighting apparatus, a cooling apparatus, or the like installed in a store may be determined by referring to the power consumption or the like of related other apparatuses. In this case, in addition to the above, measured values of other apparatuses need to be confirmed. As a result, the number of measured values to be confirmed may be doubled. Therefore, more detailed analysis may become possible, whereas the entire tendency may further be missed.

With the above examinations, new aspects of the display contents of a portable terminal and related contents have been conceived.

Hereinafter, the newly conceived display contents of a portable terminal and related contents according to an embodiment will be described.

### First Embodiment

Hereinafter, an embodiment of the present disclosure will be described with reference to drawings.

(Configuration of Facility which Performs Energy Management)

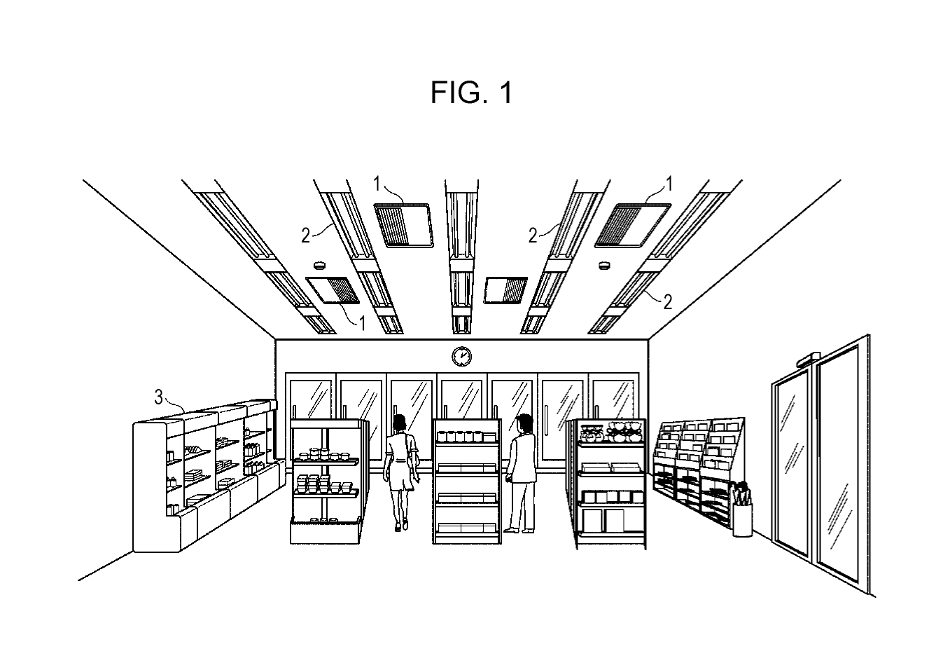

FIG. 1 is a diagram illustrating a configuration of a facility which performs energy management according to an embodiment. The configuration of the facility is not intended to be particularly limited.

At the facility, an air-conditioning apparatus 1, a lighting apparatus 2, a cooling apparatus 3 for a store selling foods or the like, and the like are provided. Furthermore, sensors, which are not illustrated in FIG. 1, are also provided at the facility. The apparatuses such as the air-conditioning apparatus 1, the lighting apparatus 2, the cooling apparatus 3, and the like are energy-consuming apparatuses.

The air-conditioning apparatus 1 adjusts the temperature, humidity, or ventilation rate inside the facility.

The lighting apparatus 2 adjusts the brightness inside and outside the facility.

The cooling apparatus 3 cools products (foods or the like) stored inside the facility.

The sensors, which are not illustrated in FIG. 1, are a wattmeter, a voltmeter, an ammeter, a temperature sensor, a humidity sensor, an infrared sensor, a human sensor, an illuminance meter, a pressure gauge, a flowmeter, a carbon dioxide sensor, a pulse counter, and the like. The above sensors measure the power consumption, operation conditions, air-sending temperature, illuminance, refrigerant pressure, temperature inside the case, use environment, and the like, and measure operation information such as electric power, the temperature and humidity inside and outside an apparatus, and the illuminance for each apparatus. Furthermore, the sensors may detect the density of carbon dioxide inside the facility, opening and closing of an automatic door, the operation conditions of the cooling apparatus, the number of people or the location of people in a sales space, or the like.

Furthermore, the sensors communicate with an external server or an integrated controller which manages apparatuses provided inside the facility, and transmit data representing measured values, detection information, and the like.

The sensors may be provided inside the apparatuses such as the air-conditioning apparatus 1, the lighting apparatus 2, and the cooling apparatus 3 provided at the facility or may be provided inside or outside the facility separately from the apparatuses.

For the case of a store selling products including foods and the like, as illustrated in FIG. 1, the cooling apparatus 3 is arranged in a part around the sales space, and an air-sending port and the like of the air-conditioning apparatus 1 and the lighting apparatus 2 are arranged on the ceiling. The air-conditioning apparatus 1 and the lighting apparatus 2 adjust environment of the entire sales space including the area in which the cooling apparatus 3 is arranged and the area of product gondolas at the center of the sales space, such as ventilation, cooling and heating, lighting, and the like.

### (System Configuration of Energy Management System)

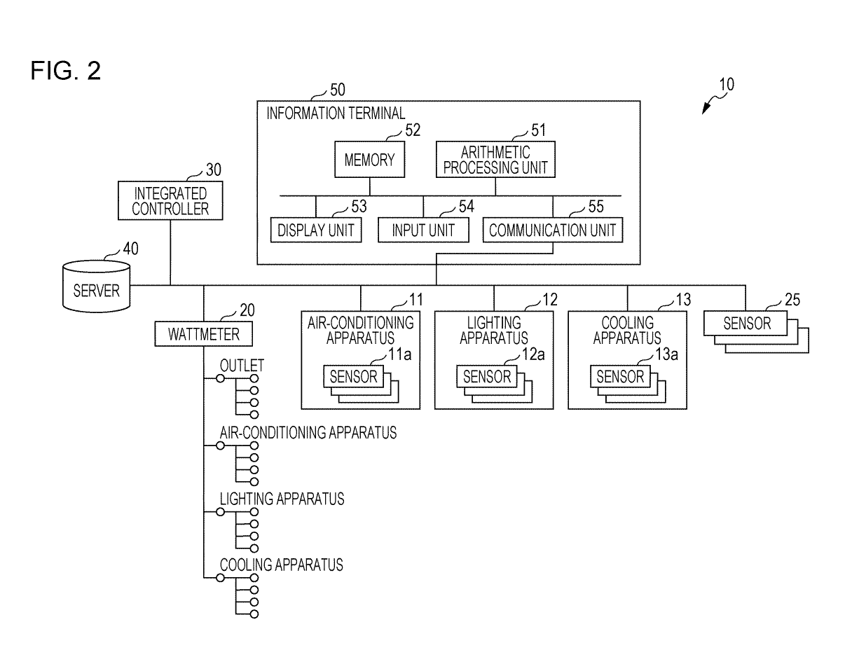

FIG. 2 is a diagram illustrating the system configuration of energy management according to an embodiment. The system configuration of the energy management is not intended to be particularly limited.

An energy management system 10 includes apparatuses provided at the facility, sensors, an integrated controller 30, a server 40, and an information terminal 50.

In FIG. 2, an air-conditioning apparatus 11, a lighting apparatus 12, and a cooling apparatus 13 are illustrated as apparatuses provided at the facility. The air-conditioning apparatus 11, the lighting apparatus 12, and the cooling apparatus 13 correspond to the air-conditioning apparatus 1, the lighting apparatus 2, and the cooling apparatus 3 in FIG. 1.

Furthermore, in FIG. 2, a wattmeter 20, one or more sensors 25 provided inside or outside the facility separately from the apparatuses (the air-conditioning apparatus 11, the lighting apparatus 12, the cooling apparatus 13, etc.), one or more sensors 11a provided inside the air-conditioning apparatus 11, one or more sensors 12a provided inside the lighting apparatus 12, and one or more sensors 13a provided inside the cooling apparatus 13 are illustrated as sensors. The wattmeter 20 may measure the power consumption and instantaneous power consumption for each apparatus.

As described above, the sensors may be provided inside the apparatuses provided in the facility or may be provided inside or outside the facility separately from the apparatuses.

The apparatuses (the air-conditioning apparatus 11, the lighting apparatus 12, the cooling apparatus 13, etc.) provided at the facility transmit data representing measured values obtained by the sensors (the sensors 11a, 12a, 13a, etc.) provided inside the apparatuses, detection information, and the like to the integrated controller 30. Furthermore, the sensors (the wattmeter 20, the sensors 25, etc.) provided inside or outside the facility separately from the apparatuses transmit data representing measured values, detection information, and the like to the integrated controller 30. The sensors provided inside the apparatuses may directly transmit data representing measured values, detection information, and the like to the integrated controller 30.

The integrated controller 30 controls the apparatuses (the air-conditioning apparatus 11, the lighting apparatus 12, the cooling apparatus 13, etc.) provided at the facility, the sensors (the sensors 11a, 12a, 13a, etc.) provided inside the apparatuses, the sensors (the wattmeter 20, the sensors 25, etc.) provided inside or outside the facility separately from the apparatuses, and the like. Furthermore, the integrated controller 30 receives data representing measured values obtained by the sensors provided inside the apparatuses, detection information, and the like from the apparatuses provided at the facility, and receives data representing measured values obtained by the sensors, detection information, and the like from the sensors provided inside or outside the facility separated from the apparatuses provided at the facility. Then, the integrated controller 30 transmits the received data representing the measured value, detection information, and the like and information indicating the sensors which performed measurement or detection to the server 40.

Furthermore, the integrated controller 30 may include an interface to be connected to an external network, such as the Internet, for example, for collection of information of surrounding environment such as meteorological information (for example, the temperature, humidity, sunshine duration, precipitation, etc. for each hour) of the location of the facility, for example, from an external server operated by a meteorological bureau or for connection to a management center or the like which manages multiple facilities in an integrated manner. Then, the integrated controller 30 transmits the information of surrounding environment such as the collected meteorological information or the like of the location of the facility to the server 40.

The server 40 is an information input/output apparatus including a storage medium such as a hard disk. The server 40 stores data representing measured values obtained by sensors, detection information, and the like received from the integrated controller 30, and stores the information of surrounding environment such as the acquired meteorological information (for example, the temperature, humidity, sunshine duration, and participation for each hour). However, data representing measured values obtained by the sensors (the sensors 11a, 12a, 13a, etc.) provided inside the apparatuses (the air-conditioning apparatus 1, the lighting apparatus 12, the cooling apparatus 13, etc.) provided at the facility and data representing measured values obtained by the sensors (the wattmeter 20, the sensors 25, etc.) provided inside or outside the facility separately from the apparatuses provided at the facility, for example, for several decades are stored in the server 40, in association with information indicating the apparatuses, information indicating the sensors, and the like. The number of years of data to be stored in the server 40 is not intended to be particularly limited.

In order that an operator performs analysis using past records and the current use conditions based on measured values obtained by the sensors and stored in the server 40, suggestion based on the analysis for improvement, and the like, the data stored in the information terminal 50 is transmitted from the server 40.

The information terminal 50 is a terminal such as a personal computer or a microcomputer. The information terminal 50 includes a display unit and an input unit, and displays information based on data received from the server 40 on the display unit. The display unit and the input unit of the information terminal 50 is implemented by a touch panel including a combination of a display device such as a liquid crystal panel or an organic electroluminescence (EL) panel and a position input device such as a touch pad, the touch panel being operable by selection on a display of the display unit.

As the information terminal 50, instead of the information terminal including a touch panel, an information terminal such as a notebook personal computer, a desktop personal computer, or the like including an input device, such as a mouse and a keyboard, and a display device may be used.

### [Configuration of Information Terminal]

Hereinafter, a configuration of the information terminal 50 will be described.

As illustrated in FIG. 2, the information terminal 50 includes an arithmetic processing unit 51, a memory 52, a display unit 53, an input unit 54, and a communication unit 55.

The arithmetic processing unit 51 is, for example, a central processing unit (CPU) or the like, and performs various arithmetic operations and various control operations.

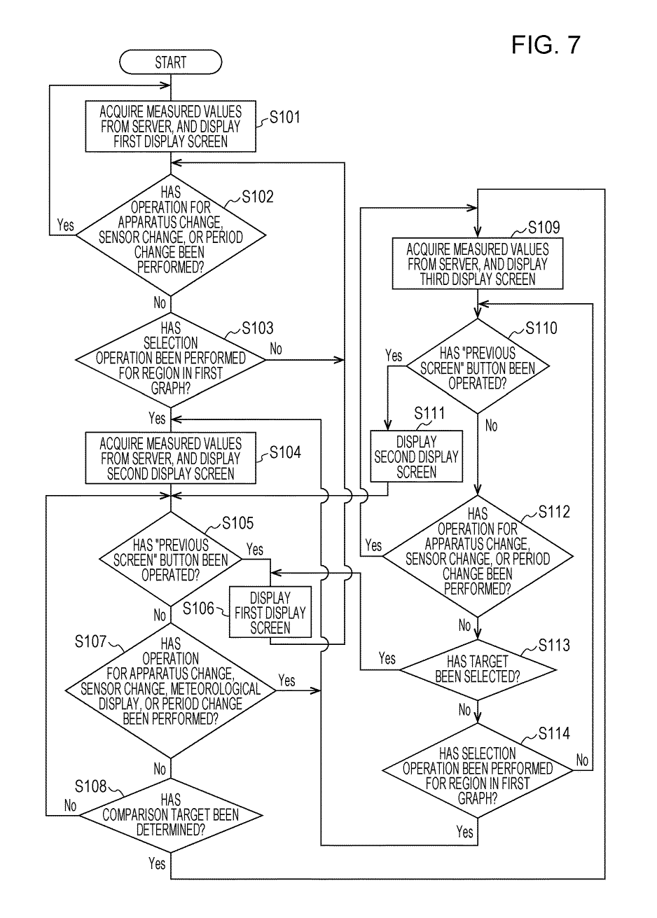

The memory 52 holds various programs and various data. A program describing a processing procedure of a flowchart illustrated in FIG. 7 is stored in the memory 52. The arithmetic processing unit 51 reads the program from the memory 52 and executes the read program. A display controller according to the present disclosure includes the arithmetic processing unit 51 and the memory 52.

The display unit 53 and the input unit 54 are implemented by a touch panel including a combination of a display device including a display such as a liquid crystal panel or an organic EL panel and a position input device such as a touch pad, the touch panel being operable by selection on the display.

The communication unit 55 is a communication unit for allowing the information terminal 50 to communicate with the integrated controller 30, the server 40, an external server, and the like. A communication unit is an example of an acquisition unit according to the present disclosure.

### <Sequence of Processing Operation by Energy Management System>

FIG. 3 is a sequence diagram illustrating an example of a processing operation by the energy management system in FIG. 2.

A sensor 80a (the sensor 11a, 11b, 11c, or the like) provided in an apparatus 80 (the air-conditioning apparatus 11, the lighting apparatus 12, the cooling apparatus 13, or the like) provided at the facility performs, for example, measurement, detection, or the like in short cycles (for example, every one minute) in a repetitive manner. Then, data representing a measured value, detection information, or the like, together with information indicating the apparatus, information indicating the sensor, and the like, are transmitted from the apparatus 80 to the integrated controller 30 (step S1), and further transmitted from the integrated controller 30 to the server 40 (step S2). Then, the server 40 stores the received data representing the measured value, detection information, or the like in association with the received information indicating the apparatus, the received information indicating the sensor, and the like (step S3). Measurement cycles may be different among sensors. The data representing the measured value, the detection information, or the like may be directly transmitted from the apparatus 80 to the server 40 or directly transmitted from the sensor 80a to the integrated controller 30 or the server 40.

A sensor 85 (the wattmeter 20, the sensor 25, or the like) which is provided inside or outside the facility separately from the apparatus 80 provided at the facility performs, for example, measurement, detection, or the like in short cycles (for example, every one minute) in a repetitive manner. Then, data representing a measured value, detection information, or the like, together with information indicating the sensor and the like, are transmitted from the sensor 85 to the integrated controller 30 (step S4), and further transmitted from the integrated controller 30 to the server 40 (step S5). Then, the server 40 stores the received data representing the measured value, detection information, or the like in association with the received information indicating the sensor and the like (step S6). Measurement cycles may be different among sensors. Furthermore, the data representing the measured value, the detection information, or the like may be directly transmitted from the sensor 85 to the server 40.

The information terminal 50 requests the server 40 to transmit data and the like (step S7). In response to the transmission request, the server 40 transmits the requested data and the like to the information terminal 50 (step S8). Instead of direct communication between the information terminal 50 and the server 40, communication may be performed via the integrated controller 30.

Transmission data is, according to need, transmitted and received via a network including a signal converter or a relay unit for converting a signal level of an electric signal or a communication method, a converter for the case where a communication protocol or data format is different between relay units, a controller, and the like. For simplification of FIG. 3, illustration of the above network is omitted.

Furthermore, typically, for communication between apparatuses forming a network, along with data exchange, communication messages about establishment of communication at a lower level (a protocol as a more fundamental communication apparatus), terminal confirmation, request, response, and the like are generated. However, this is within the category of a general communication protocol. Therefore, the above is not intended to be particularly limited in an embodiment.

In the energy management system 10, control of the apparatuses or sensors provided at the facility is also one of important functions. The information terminal 50 may transmit a control instruction to an apparatus or a sensor provided at the facility and receive a response from the apparatus or the sensor.

### (Display Screen of Information Terminal)

According to an embodiment, on the display of the display unit 53 of the information terminal 50, three display screens (a first display screen, a second display screen, and a third display screen) are mainly displayed.

As described above, in an embodiment, there are sensors provided inside apparatuses and sensors provided inside or outside the facility separately from the apparatuses. Hereinafter, a sensor provided inside an apparatus will be referred to as an “intra-apparatus sensor”, and a sensor provided inside or outside the facility separately from an apparatus will be referred to as an “extra-apparatus sensor” in an appropriate manner.

Furthermore, regarding in an extra-apparatus sensor, no apparatus at which the extra-apparatus sensor is provided exists. For a simpler illustration, however, a target including the sensor is regarded as being “extra-apparatus”, and the “extra-apparatus” is regarded as an apparatus. For example, description will be provided such that apparatuses different from the air-conditioning apparatus 11 include an “extra-apparatus”, as well as the actual apparatuses such as the lighting apparatus 12, the cooling apparatus 13, and the like.

### [First Display Screen]

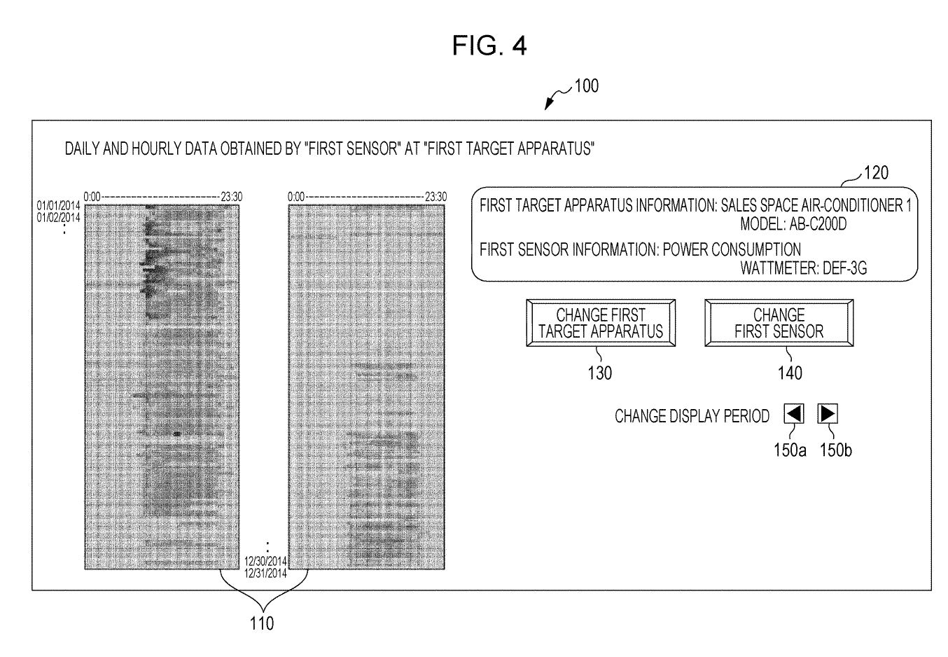

FIG. 4 is a diagram illustrating an example of a first display screen displayed on the display of the display unit 53 of the information terminal 50 according to an embodiment.

On a first display screen 100, in a first graph 110 where a first axis represents dates and a second axis represents hours, measured values for a period of one year which are obtained by a sensor (the wattmeter 20, the sensor 25, 11a, 12a, 13a, or the like) and related to an operation of an energy-consuming apparatus are indicated such that sizes of the measured values are represented by different thicknesses of the same color. For example, a larger measured value may be indicated by a darker point, and a smaller measured value may be indicated by a lighter point. Alternatively, a larger measured value may be indicated by a lighter point, and a smaller measured value may be indicated by a darker point.

The graph where the first axis represents dates and the second axis represents hours will be referred to as a “first graph” in an appropriate manner.

In the example of the first display screen 100 in FIG. 4, measured values are indicated in the first graph 11 such that sizes of the measured values are represented by different thicknesses of the same color. However, for example, sizes of the measured values may be represented by different display colors.

Furthermore, in the example of the first display screen 100, measured values for a period of one year are indicated in the first graph 110. However, measured values for a period of one month may be indicated or measured values for a period of three months may be indicated. Thus, measured values for a period of a plurality of days may be indicated.

In the first graph 110, for example, as illustrated in FIG. 4, blocks which represent half-hourly power consumptions whose sizes are represented by different thicknesses are arranged in the direction of the second axis, and daily data of the power consumptions are arranged in the direction of the first axis.

Measured values indicated in the first graph 110 on the first display screen 100 will be referred to as “first measured values”, a sensor which obtains the measured values will be referred to as a “first sensor”, and an apparatus at which the sensor is provided will be referred to as a “first target apparatus”. As described above, in the case of an extra-apparatus sensor, no apparatus at which the extra-apparatus sensor is provided exists. In this case, however, for a simpler illustration, a “first target apparatus” will be regarded as being “extra-apparatus”.

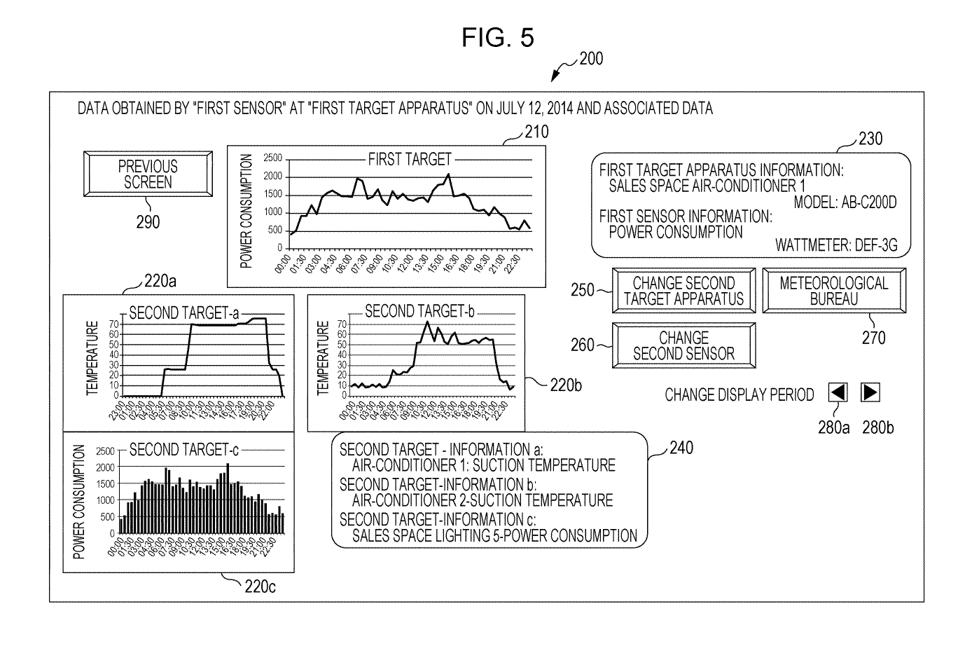

When an operator selects any one of regions of the first graph 110, the selection causes the display contents of the display of the display unit 53 of the information terminal 50 to be switched from the first display screen to a second display screen. FIG. 5 illustrates an example of the second display screen. The second display screen will be described later with reference to FIG. 5.

The first display screen 100 includes a region 120 which indicates information of a first sensor which obtained a first measured value of the first graph 110 and a first target apparatus at which the first sensor is provided (a measurement location or the like in the case where the first sensor is an extra-apparatus sensor).

The first display screen 100 further includes a “first target apparatus change” button 130, a “first sensor change” button 140, and “display period change” buttons 150a and 150b.

The first target apparatus change” button 130 is a region to be selected by an operator to switch a first measured value of the first graph 110 to a measured value obtained by a sensor provided at a different apparatus. For example, in the case where the first sensor which obtained the first measured value of the first graph 110 at the time of selection is an intra-apparatus sensor provided inside the air-conditioning apparatus 11, a measured value obtained by an intra-apparatus sensor provided inside an apparatus different from the air-conditioning apparatus 11 or an extra-apparatus sensor being “extra-apparatus” is indicated as the first measured value in the first graph 110. Furthermore, in the case where the first sensor which obtained the first measured value of the first graph 110 at the time of selection is an extra-apparatus sensor, a measured value obtained by an intra-apparatus sensor provided inside an apparatus is indicated as the first measured value in the first graph 110.

The “first sensor change” button 140 is a region to be selected by an operator to switch a first measured value of the first graph 110 to a measured value of a different sensor provided within the same apparatus. For example, in the case where the first sensor which obtained the first measured value of the first graph 110 at the time of selection is an intra-apparatus sensor provided inside the air-conditioning apparatus 11, a measured value obtained by a different intra-apparatus sensor provided within the air-conditioning apparatus 11 is indicated as the first measured value in the first graph 110. Furthermore, in the case where the first sensor which obtained the first measured value of the first graph 110 at the time of selection is an extra-apparatus sensor, a measured value obtained by a different extra-apparatus sensor being “extra-apparatus” is indicated as the first measured value in the first graph 110.

The display period change” button 150a is a region to be selected by an operator to switch the display period of a first measured value of the first graph 110 to the previous year. Furthermore, the display period change” button 150b is a region to be selected by an operator to switch the display period of a first measured value of the first graph 110 to the next year.

The first graph 110 on the first display screen represents measured values as a third element (for example, power consumption) using a two-dimensional graph where each of the first axis and the second axis is a time-scale axis such that sizes of the measured values are represented by different thicknesses. Therefore, while using the two-dimensional graph, three elements (dates, hours, and measured values) may be indicated on a single display screen. Consequently, an operator may understand the entire tendency of measured values with less operation.

Furthermore, for example, to obtain a bird's eye view of measured values for the whole year, by generating a first graph 110 where the first axis represents one year, a bird's eye view of tendencies of the whole year may be obtained, and the entire tendency may be understood easily.

Furthermore, the first graph 110 does not simply indicate the total amount of measured values (for example, power consumptions) for a single day. The first graph 110 represents hourly measured values (for example, power consumptions) on a specific date. Therefore, for example, only with a first graph 110, a confirmation as to whether failing to turn off the power at night caused waste of electric power during midnight, whether an amount of electric power larger than usual was consumed during daytime, or the like may be achieved. In this case, for example, in the case where there is a problem in power consumption or the like, failing to find a cause of the problem may be avoided. That is, hourly measured values (for example, power consumptions) on a specific date may be obtained, and with the same first graph 110, for example, a bird's eye view of measured values for the whole year may also be obtained.

As described above, being able to observe changes for a target period with a bird's eye view allows a characteristic period (date and time or the like in which a characteristic change is observed) to be easily found. Accordingly, a motivation to refer to more detailed hourly changes of first measured values indicated in the first graph 110 and measured values obtained by a different sensor (for example, a different sensor at the same apparatus, a sensor at a different apparatus, or the like), while focusing on the characteristic period, may be generated (awareness may be prompted).

### [Second Display Screen]

FIG. 5 is a diagram illustrating an example of a second display screen displayed on the display of the display unit 53 of the information terminal 50 according to an embodiment.

On a second display screen 200, in second graphs 210, 220a, 220b, and 220c where the first axis is a time-scale axis and the second axis represents measured values, measured values for a period of one day obtained by sensors (the wattmeter 20, the sensors 25, 11a, 12a, 13a, and the like) are indicated.

A graph where the first axis represents hours and the second axis represents measured values will be referred to as a “second graph” in an appropriate manner. As the second graph, a general graph such as, for example, a line graph, a bar graph, or the like may be used. The number of days of second measured values indicated in the second graph is not necessarily one and may be two, three, or the like as long as the number of days is smaller than that of the first graph.

In the case where switching from the first display screen 100 to the second display screen 200 is made, measured values for a date specified by an operator, the measured values being obtained by the first sensor which obtains the first measured values of the first graph 110, are indicated in the second graph 210. Furthermore, measured values for the date specified by the operator, the measured values being obtained by sensors different from the first sensor which obtains the first measured values of the first graph 110, are indicated in the second graphs 220a, 220b, and 220c. However, the date specified by the operator is equal to the date corresponding to one of the regions of the first graph 110 on the first display screen for which a selection operation has been performed by the operator.

Measured values indicated in the second graph 210 on the second display screen 200 will be referred to as “first measured values”, a sensor which obtains the measured values will be referred to as a “first sensor”, and an apparatus at which the sensor is provided will be referred to as a “first target apparatus”. Furthermore, measured values indicated in the second graphs 220a, 220b, and 220c will be referred to as “second measured values”, a sensor which obtains the measured values will be referred to as a “second sensor”, and an apparatus at which the sensor is provided will be referred to as a “second target apparatus”. As described above, in the case where a sensor is an extra-apparatus sensor, no apparatus at which the extra-apparatus sensor is provided exists. In this case, however, for a simpler illustration, a “first target apparatus” and a “second target apparatus” will be regarded as being “extra-apparatus”.

For example, in the case where the first sensor which obtained the first measured values of the first graph 110 at the time of switching is an intra-apparatus sensor provided inside the air-conditioning apparatus 11, the second measured values of the second graphs 220a, 220b, and 220c are switched to measured values obtained by sensors, such as a different intra-apparatus sensor provided inside the air-conditioning apparatus 11, an intra-apparatus sensor provided inside an apparatus different from the air-conditioning apparatus 11, or an extra-apparatus sensor being “extra-apparatus”.

Furthermore, in the case where the sensor which obtained the first measured values of the first graph 110 at the time of switching is an extra-apparatus sensor, the second measured values of the second graphs 220a, 220b, and 220c are switched to measured values of sensors, such as an intra-apparatus sensor provided in an apparatus or a different extra-apparatus sensor being “extra-apparatus”.

In the example of the second display screen 200 in FIG. 5, the number of second graphs indicating the second measured values is three, that is, the second graphs 220a, 220b, and 220c. However, the number of second graphs may be one, two, four, or more.

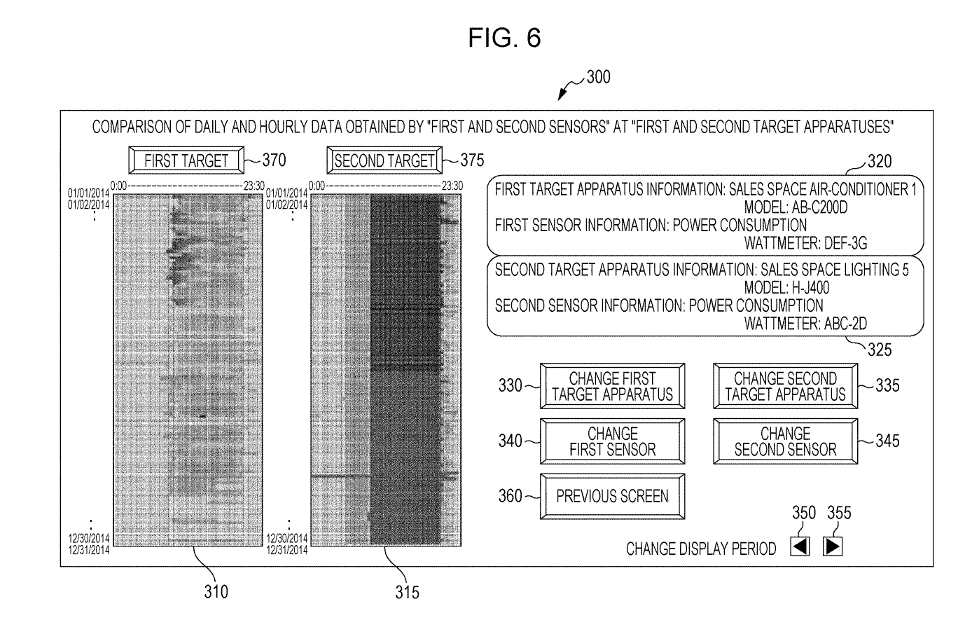

In the case where any one of regions of the second graphs 220a, 220b, and 220c is selected by an operator, the selection causes the display contents of the display on the display unit 53 of the information terminal 50 to be switched from the second display screen to a third display screen. FIG. 6 illustrates an example of the third display screen. The third display screen will be described later with reference to FIG. 6.

The second display screen 200 includes a region 230 which indicates information of a first sensor which obtained a first measured value of the second graph 210 and a first target apparatus at which the first sensor is provided (a measurement location or the like in the case where the first sensor is an extra-apparatus sensor). The second display screen 200 further includes a region 240 which indicates information of second sensors which obtained second measured values of the second graphs 220a, 220b, and 220c and second target apparatuses at which the second sensors are provided (a measurement location or the like in the case where the second sensor is an extra-apparatus sensor).

Furthermore, the second display screen 200 includes a “second target apparatus change” button 250, a “second sensor change” button 260, a “meteorological bureau” button 270, and “display period change” buttons 280a and 280b.

The “second target apparatus change” button 250 is a region to be selected by an operator to switch second measured values of the second graphs 220a, 220b, and 220c to measured values obtained by sensors of different apparatuses. For example, in the case where the second sensor which obtained the second measured value of the second graph 220a at the time of selection is an intra-apparatus sensor provided inside the air-conditioning apparatus 11, a measured value obtained by an intra-apparatus sensor provided inside an apparatus different from the air-conditioning apparatus 11 or an extra-apparatus sensor being “extra-apparatus” is indicated as the second measured value in the second graph 220a. Furthermore, in the case where the second sensor which obtained the second measured value of the second graph 220a at the time of selection is an extra-apparatus sensor, a measured value obtained by an intra-apparatus sensor provided inside an apparatus is newly indicated as the second measured value in the second graph 220a.

The “second sensor change” button 260 is a region to be selected by an operator to switch second measured values of the second graphs 220a, 220b, and 220c to measured values of different sensors provided within the same apparatus. For example, in the case where the second sensor which obtained the second measured value of the second graph 220a at the time of selection is an intra-apparatus sensor provided inside the air-conditioning apparatus 11, a measured value obtained by a different intra-apparatus sensor provided inside the air-conditioning apparatus 11 is indicated as the second measured value in the second graph 220a. Furthermore, in the case where the second sensor which obtained the second measured value of the second graph 220a at the time of selection is an extra-apparatus sensor, a measured value obtained by a different extra-apparatus sensor being “extra-apparatus” is indicated as the second measured value in the second graph 220a.

The “meteorological bureau” button 270 is a region to be selected by an operator to switch part or all of the second measured values of the second graphs 220a, 220b, and 220c to meteorological information. However, meteorological information is indicated by a second graph where the first axis is a time-scale axis and the second axis represents meteorological information.

The “display period change” button 280a is a region to be selected by an operator to switch the display period of the first measured value of the second graph 210 and the second measured values of the second graphs 220a, 220b, and 220c to the previous day. Furthermore, the “display period change” button 280b is a region to be selected by an operator to switch the display period of the first measured value of the second graph 210 and the second measured values of the second graphs 220a, 220b, and 220c to the next day.

Furthermore, the second display screen 200 includes a “previous screen” button 290. The “previous screen” button 290 is a region to be selected by an operator to return from the second display screen 200 to the first display screen 100.

Advantages of a second graph on the second display screen 200 will be described below.

Comparative evaluation of target apparatuses may be performed by referring to the state of different apparatuses at the same period. In this case, evaluation results (for example, power consumptions) corresponding to a target date not a whole year may be presented, and thus, the second graph may be simplified. Consequently, an increase in the amount of data to be confirmed may be reduced to the minimum necessary, and micro-analysis may be supported.

Furthermore, on the second display screen 200, measured values for a specific period of time may be indicated, as described above. Thus, the second graphs are simple, and more detailed hourly changes in first measured values obtained by a first sensor and second measured values obtained by a second sensor may be indicated.

As a result, for example, in the case where an air-conditioner is operating during the midnight of a certain day, if the power of a lighting apparatus arranged in an area which is affected by output of the air-conditioner is in an off state during the midnight of the day, it may be determined that failing to turning off the power of the air-conditioner caused waste of electric power.

In contrast, for example, in the case where an air-conditioner is operating during the midnight of a certain day, if the power of a lighting apparatus arranged in an area affected by output of the air-conditioner is in an on state during the midnight of the day, it may be determined that, for example, a stocktaking operation was being done during the midnight.

Similarly, in the case where the amount of electric power consumed by an air-conditioner during the daytime of a certain day is larger than other normal days, if measured values obtained by a door opening and closing sensor arranged in an area affected by output of the air-conditioner indicate a high door opening and closing frequency during the daytime of the day, it may be determined that frequent intrusion of outside air caused the power consumption of the air-conditioner to be increased during the daytime of the day.

In contrast, in the case where the amount of electric power consumed by an air-conditioner during the daytime of a certain day is larger than other normal days, if measured values obtained by a door opening and closing sensor arranged in an area affected by output of the air-conditioner indicate a low door opening and closing frequency during the daytime of the day, it may be determined that a factor, such as a too-high setting temperature of the air-conditioner, which is different from influence of the outside air, caused the power consumption of the air-conditioner to be increased during the daytime of the day, and a different sensor at the apparatus and measured values obtained by the different sensor may be checked.

As described above, a cause for which countermeasures are to be taken may be easily clarified by less operation.

Furthermore, advantages for a case where information of surrounding environment such as meteorological information is indicated in part or all of the second graphs 220a, 220b, and 220c will be described below. In this case, measured obtained by an intra-apparatus sensor provided inside an apparatus provided at the facility and an extra-apparatus sensor provided inside or outside the facility and surrounding environment such as meteorological information are indicated on the same screen. Therefore, comparison of characteristic tendencies may be easily achieved.

For example, a combination of measured values obtained by a temperature sensor provided inside the facility and meteorological data of meteorological information measured outside the facility is indicated. In this case, a relationship between a change of the temperature inside the facility and the outside air temperature or humidity in the surrounding area may be confirmed. Furthermore, for example, by referring to meteorological information of an area in which the facility is located, a combination with the power consumption of an air-conditioner for which cooling is set is indicated. In this case, when the outside air temperature is relatively high in the case where the amount of power consumption of an air-conditioner apparatus is relatively large, it may be determined that a high outside air temperature caused the power consumption of the air-conditioner to be increased (phenomenon normally considered). In contrast, in the case where the amount of power consumption of the air-conditioner for which cooling is set is relatively large even when the outside air temperature is relatively low, it may be determined that an improper setting temperature caused the power consumption of the air-conditioner to be increased, irrespective of the outside air temperature. Accordingly, for example, a cause for the increase in the power consumption of the air-conditioner may be clarified, and appropriate countermeasures may be considered.

As measured values obtained outside the facility, measured values related to a same type of apparatus at a different facility managed by the management center as well as meteorological information may be considered. For example, a combination of measured values of power consumption of a target apparatus and measured values of power consumption of a same type of apparatus at a different facility management by the management center is indicated. In this case, a confirmation as to whether similar phenomena are occurring concurrently at multiple facilities may be made. Furthermore, a determination may be made taking into consideration influence of an event which serves as a common external factor.

### [Third Display Screen]

FIG. 6 is a diagram illustrating an example of a third display screen displayed on the display of the display unit 53 of the information terminal 50 according to an embodiment.

On a third display screen 300, in graphs (first graphs) 310 and 315 where a first axis represents dates and a second axis represents hours, measured values for a period of one year which are obtained by sensors (the wattmeter 20, the sensor 25, 11a, 12a, 13a, or the like) and related to an operation of energy-consuming apparatuses are indicated such that sizes of the measured values are represented by different thicknesses of the same color. For example, a larger measured value may be indicated by a darker point, and a smaller measured value may be indicated by a lighter point. Alternatively, a larger measured value may be indicated by a lighter point, and a smaller measured value may be indicated by a darker point.

In the example of the third display screen 300 in FIG. 6, measured values are indicated in the first graphs 310 and 315 such that sizes of the measured values are represented by different thicknesses of the same color. However, sizes of the measured values may be represented by different display colors.

Furthermore, in the example of the third display screen 300, measured values for a period of one year are indicated in the first graphs 310 and 315. However, measured values for a period of one month may be indicated or measured values for a period of three months may be indicated. Thus, measured values for a period of a plurality of days may be indicated.

In the first graphs 310 and 315, for example, as illustrated in FIG. 6, blocks which represent half-hourly power consumptions whose sizes are represented by different thicknesses are arranged in the direction of the second axis, and daily data of the power consumptions are arranged in the direction of the first axis.

In the case where switching is made from the second display screen 200 to the third display screen 300, measured values for one year including the date indicated in the second graph, the measured values being obtained by a first sensor which obtains first measured values of the second graph 210 on the second display screen 200, are indicated in the first graph 310. Furthermore, measured values for one year including the date indicated in the second graph selected by an operator from among the second graphs 220a, 220b, and 220c of the second display screen 200, the measured values being obtained by a second sensor which obtains second measured values of the selected second graph, are indicated in the first graph 315.

Measured values indicated in the first graph 310 on the third display screen 300 will be referred to as “first measured values”, a sensor which obtains the measured values will be referred to as a “first sensor”, and an apparatus at which the sensor is provided will be referred to as a “first target apparatus”. Furthermore, measured values indicated in the first graph 315 will be referred to as “second measured values”, a sensor which obtains the measured values will be referred to as a “second sensor”, and an apparatus at which the sensor is provided will be referred to as a “second target apparatus”. As described above, in the case of an extra-apparatus sensor, no apparatus at which the extra-apparatus sensor is provided exists. In this case, however, for a simpler illustration, a “first target apparatus” and a “second target apparatus” will be regarded as being “extra-apparatus”.

In the case where an operator selects any one of regions of the first graphs 310 and 315, the selection causes the display contents of the display of the display unit 53 of the information terminal 50 from the third display screen to the second display screen, an example of which is illustrated in FIG. 5.

The third display screen 300 includes a region 320 which indicates information of a first sensor which obtained a first measured value of the first graph 310 and a first target apparatus at which the first sensor is provided (a measurement location or the like in the case where the first sensor is an extra-apparatus sensor). The third display screen 300 further includes a region 325 which indicates information of a second sensor which obtained a second measured value of the first graph 315 and a second target apparatus at which the second sensor is provided (a measurement location or the like in the case where the second sensor is an extra-apparatus sensor).

Furthermore, the third display screen 300 includes a “first target apparatus change” button 330, a “first sensor change” button 340, a “second target apparatus change” button 335, a “second sensor change” button 345, and “display period change” buttons 350 and 355.

The “first target apparatus change” button 330 is a region to be selected by an operator to switch first measured values of the first graph 310 to measured values obtained by a sensor of a different apparatus. For example, in the case where the first sensor which obtained the first measured values of the first graph 310 at the time of selection is an intra-apparatus sensor provided inside the air-conditioning apparatus 11, measured values obtained by an intra-apparatus sensor provided inside an apparatus different from the air-conditioning apparatus 11 or an extra-apparatus sensor being “extra-apparatus” are indicated as the first measured values in the first graph 310. Furthermore, in the case where the first sensor which obtained the first measured values of the first graph 310 at the time of selection is an extra-apparatus sensor, measured values obtained by an intra-apparatus sensor provided inside an apparatus are indicated as the first measured values in the first graph 310.

The “first sensor change” button 340 is a region to be selected by an operator to switch the first measured values of the first graph 310 to measured values obtained by a different sensor provided in the same apparatus. For example, in the case where the first sensor which obtained the first measured values of the first graph 310 at the time of selection is an intra-apparatus sensor provided inside the air-conditioning apparatus 11, measured values obtained by a different intra-apparatus sensor provided inside the air-conditioning apparatus 11 are indicated as the first measured values in the first graph 310. Furthermore, in the case where the first sensor which obtained the first measured values of the first graph 310 at the time of selection is an extra-apparatus sensor, measured value obtained by a different extra-apparatus sensor being “extra-apparatus” are indicated as the first measured values in the first graph 310.

The “second target apparatus change” button 335 is a region to be selected by an operator to switch the second measured values of the first graph 315 to measured values obtained by a sensor at a different apparatus. For example, in the case where the second sensor which obtained the second measured values of the first graph 315 at the time of selection is an intra-apparatus sensor provided inside the air-conditioning apparatus 11, measured values obtained by an intra-apparatus sensor provided inside an apparatus different from the air-conditioning apparatus 11 or an extra-apparatus sensor being “extra-apparatus” are indicated as the second measured values in the first graph 310. Furthermore, in the case where the second sensor which obtained the second measured values of the first graph 315 at the time of selection is an extra-apparatus sensor, measured value obtained by an intra-apparatus sensor provided in an apparatus are indicated as the second measured values in the first graph 315.

The “second sensor change” button 345 is a region to be selected by an operator to switch the second measured values of the first graph 315 to measured values obtained by a different sensor provided within the same apparatus. For example, in the case where the second sensor which obtained the second measured values of the first graph 315 at the time of selection is an intra-apparatus sensor provided inside the air-conditioning apparatus 11, measured values obtained by a different intra-apparatus sensor provided inside the air-conditioning apparatus 11 are indicated as the second measured values in the first graph 315. Furthermore, in the case where the second sensor which obtained the second measured values of the first graph 315 at the time of selection is an extra-apparatus sensor, measured values obtained by a different extra-apparatus sensor being “extra-apparatus” are indicated as the second measured values in the first graph 315.

The “display period change” button 350 is a region to be selected by an operator to switch the display period of the first measured values of the first graph 310 and the second measured values of the first graph 315 to the previous year. Furthermore, the “display period change” button 355 is a region to be selected by an operator to switch the display period of the first measured values of the first graph 310 and the second measured values of the first graph 315 to the next year.

Furthermore, the third display screen 300 includes a “previous screen” button 360. The “previous screen” button 360 is a region to be selected by an operator to return from the third display screen 300 to the second display screen 200.

Furthermore, the third display screen 300 includes a “first target” button 370 and a “second target” button 375. The “first target” button 370 is a region to be selected by an operator to indicate the first measured values of the first graph 310 on the third display screen 300 as the first measured values of the first graph 110 on the first display screen 100. The “second target” button 375 is a region to be selected by an operator to indicate the second measured values of the first graph 315 on the third display screen 300 to the first measured values of the first graph 110 on the first display screen 100.

Advantages of the first graph of the third display screen will be described below.

On the third display screen 300, the first measured values obtained by the first sensor at the first target apparatus and the second measured values obtained by the second sensor at the second target apparatus are indicated in parallel in the first graphs 310 and 315, which have the same form as the first graph 110 on the first display screen 100. Accordingly, the entire tendency of measured values (for example, power consumption) for a year obtained by the second sensor at the second target apparatus may be obtained. Thus, macro-analysis as well as micro-analysis about the second target apparatus may be easily supported compared to the first target apparatus, and a confirmation as to whether a target phenomenon occurs in a multiple sensors or multiple apparatuses may be achieved quickly.

Furthermore, in the case where similar tendencies may be observed in both of the measured values, it may be determined that there is a cause common in both of the target apparatuses not in only one of the target apparatuses. For example, in the case where power consumption of the first target apparatus and power consumption of the second target apparatus are increased in the same period of time, it may be determined that there is a cause common in both the first target apparatus and the second target apparatus.

### (Process of Information Terminal)

FIG. 7 is a flowchart illustrating a processing operation of the information terminal of FIG. 2.

For example, immediately after the system is activated or when a selection to display the first display screen is performed by an operator on a menu screen, for example, the arithmetic processing unit 51 of the information terminal 50 requests the server 40 to transmit data representing measured values for an initially set year obtained by an initially set sensor. In response to the transmission request, the arithmetic processing unit 51 receives from the server 40 the data representing the measured values for the year corresponding to the transmission request. Based on the received data representing the measured values for the year, the arithmetic processing unit 51 displays on the display unit 53 the first display screen 100 on which the measured values are indicated as the first measured values in the first graph 110 (step S101). The transmission request is not particularly limited. Instead of the transmission request for the data representing the measured values for the initially set year obtained by the initially set sensor, for example, a transmission request for data representing measured values for a year specified by an operator obtained by a sensor which is specified in advance by the operator may be transmitted.

The arithmetic processing unit 51 of the information terminal 50 monitors an operation on the first display screen 100 by the operator, and determines whether or not the operator has performed any one of an operation for apparatus change (selection of the “first target apparatus change” button 130), an operation for sensor change (selection of the “first sensor change” button 140), and an operation for period change to the previous year or the next year (selection of the “display period change” button 150a or 150b) (step S102).

In the case where any one of the operation for apparatus change, the operation for sensor change, and the operation for period change to the previous year or the next year has been performed (S102: Yes), the next processing is performed in step S101.

The arithmetic processing unit 51 of the information terminal 50 requests the server 40 to transmit data representing measured values for a year corresponding to an operation by the operator. In response to the transmission request, the arithmetic processing unit 51 receives from the server 40 the data representing the measured values for the year corresponding to the transmission request. Based on the received data representing the measured values for the year, the arithmetic processing unit 51 indicates on the display unit 53 the first display screen 100 on which the measured values are indicated as the first measured values in the first graph 110.

In the case where the operation for apparatus change is performed, the transmission request is a request to transmit data representing measured values for a year indicated in the first graph 110, the measured values being obtained by a sensor at an apparatus different from that indicated in the first graph 110 at the current point in time. Furthermore, in the case where the operation for sensor change is performed, the transmission request is a request to transmit data representing measured values for a year indicated in the first graph 110, the measured values being obtained by a different sensor at the same apparatus as that indicated in the first graph 110 at the current point in time. Furthermore, in the case where the operation for period change to the previous year is performed, the transmission request is a request to transmit data representing measured values for the year previous to the year indicated in the first graph 110, the measured values being obtained by the same sensor as that indicated in the first graph 110 at the current point in time. Furthermore, in the case where the operation for period change to the next year is performed, the transmission request is a request to transmit data representing measured values for the year next to the year indicated in the first graph 110, the measured values being obtained by the same sensor as that indicated in the first graph 110 at the current point in time.

In the case where none of the operation for apparatus change, the operation for sensor change, and the operation for period change to the previous year or the next year has been performed (S102: No), the arithmetic processing unit 51 of the information terminal 50 determines whether or not the operator has performed a selection operation for a region of the first graph 110 (step S103). In the case where no selection operation has been performed for a region of the first graph 110 (S103: No), the process returns to the processing of step S102.

In the case where a selection operation has been performed for a region of the first graph 110 (S103: Yes), the next processing is performed in step S104.

The arithmetic processing unit 51 of the information terminal 50 requests the server 40 to transmit data representing measured values for a date specified by the operator, the measured values being obtained by sensors (three sensors, in the example of the second display screen in FIG. 5) different from those indicated in the first graph 110 at the current point in time. The date specified by the operator corresponds to a region of the first graph 110 for which the operator has performed a selection operation. In response to the transmission request, the arithmetic processing unit 51 receives from the server 40 the data representing the measured values for the date specified by the operator, the measured values being obtained by the sensors (three sensors) corresponding to the transmission request. Then, the arithmetic processing unit 51 displays the second display screen. The second graph 210 on the second display screen is displayed based on the data representing the measured values for the date specified by the operator among data used for indication of the first measured values in the first graph 110. Furthermore, the second graphs 220a, 220b, and 220c are displayed based on the data representing the measured values for the date specified by the operator, the measured values being obtained by the three sensors and received in response to the transmission request.

The three sensors which obtain the second measured values indicated in the second graphs 220a, 220b, and 220c at the time of switching from the first display screen 100 to the second display screen 200 are not particularly limited, and may be, for example, an initially set sensor, a sensor specified in advance by the operator, or the like.

The arithmetic processing unit 51 of the information terminal 50 monitors an operation by the operator on the second display screen 200, and determines whether or not the operator has performed a selection operation for the “previous screen” button 290 (S105). In the case where a selection operation has been performed for the “previous screen” button 290 (S105: Yes), the arithmetic processing unit 51 of the information terminal 50 displays on the display unit 53 the first display screen 100, which is the screen displayed before switching to the second display screen 200 (step S106), and the processing of step S102 is performed.

In the case where a selection operation has not been performed for the “previous screen” button 290 (S105: No), the arithmetic processing unit 51 of the information terminal 50 determines whether or not the operator has performed any one of an operation for apparatus change (selection of the “second target apparatus change” button 250), an operation for sensor change (selection of the “second sensor change” button 260), an operation for meteorological display (selection of the “meteorological bureau” button 270), and an operation for period change to the previous day or the next day (selection of the “display period change” button 280a or 280b) (step S107).

In the case where any one of the operation for apparatus change, the operation for sensor change, the operation for meteorological display, and the operation for period change to the previous day or the next day has been performed (S107: Yes), the next processing is performed in step S104.

The arithmetic processing unit 51 of the information terminal 50 requests the server 40 to transmit data representing measured values for a day for the second graphs 220a, 220b, and 220c corresponding to an operation by the operator. In response to the transmission request, the arithmetic processing unit 51 receives from the server 40 the data representing the measured values for the day for the second graphs 220a, 220b, and 220c corresponding to the transmission request. Then, based on the received data representing the measured values for the day for the second graphs 220a, 220b, and 220c, the arithmetic processing unit 51 displays on the display unit 53 the second display screen 200 on which the measured values are indicated as the second measured values in the second graphs 220a, 220b, and 220c.

In the case where the operation for apparatus change is performed, the transmission request is a request to transmit data representing measured values for the day indicated in the second graphs 220a, 220b, and 220c, the measured values being obtained by sensors at an apparatus different from that indicated in the second graphs 220a, 220b, and 220c at the current point in time. Furthermore, in the case where the operation for sensor change is performed, the transmission request is a request to transmit data representing measured values for the day indicated in the second graphs 220a, 220b, and 220c, the measured values being obtained by different sensors at the same apparatus as those indicated in the second graphs 220a, 220b, and 220c at the current point in time. Furthermore, in the case where the operation for meteorological display is performed, the transmission request is a request to transmit meteorological data representing meteorological information of the location of the facility for the day indicated in the second graphs 220a, 220b, and 220c. In the case where the operation for period change to the previous day is performed, the transmission request is a request to transmit data representing measured values for the day previous to the day indicated in the second graphs 220a, 220b, and 220c, the measured values being obtained by the same sensors as those indicated in the second graphs 220a, 220b, and 220c at the current point in time. Furthermore, in the case where the operation for period change to the next day is performed, the transmission request is a request to transmit data representing measured values for the day next to the day indicated in the second graphs 220a, 220b, and 220c, the measured values being obtained by the same sensors as those indicated in the second graphs 220a, 220b, and 220c at the current point in time.

In the case where none of the operation for apparatus change, the operation for sensor change, the operation for meteorological display, and the operation for period change to the previous day or the next day has been performed (S107: No), the arithmetic processing unit 51 of the information terminal 50 determines whether or not a determination operation for a comparison target (selection operation for any of the second graphs 220a, 220b, and 220c) has been performed (step S108). In the case where no determination operation for a comparison target has been performed (S108: No), the process returns to the processing of step S105.

In the case where a determination operation for a comparison target has been performed (S108: Yes), the next processing is performed in step S109.

The arithmetic processing unit 51 of the information terminal 50 requests the server 40 to transmit data representing measured values for a year including the date indicated in the second graph determined as the comparison target among the second graphs 220a, 220b, and 220c, the measured values being obtained by the second sensor which obtains the second measured values of the second graph. In response to the transmission request, the arithmetic processing unit 51 receives the data representing the measured values from the server 40 for the year corresponding to the transmission request. Then, the arithmetic processing unit 51 displays a third display screen. Based on the data which is related to the second graph 210 of the second display screen 200 and used for the indication of the acquired first measured values of the first graph 110, the first graph 310 on the third display screen is displayed. Furthermore, the first graph 315 is related to the second graph that is selected by the operator from among the second graphs 220a, 220b, and 220c on the second display screen 200, and is displayed based on the data representing the measured values for the year received as a response to the transmission request.

The arithmetic processing unit 51 of the information terminal 50 monitors an operation by the operator on the third display screen 300, and determines whether or not the operator has performed a selection operation for the “previous screen” button 360 (step S110). In the case where a selection operation has been performed for the “previous screen” button 360 (S110: Yes), the arithmetic processing unit 51 of the information terminal 50 displays on the display unit 53 the second display screen 200, which is the screen displayed before switching to the third display screen 300 (step S111).

In the case where a selection operation has not been performed for the “previous screen” button 360 (S110: No), the arithmetic processing unit 51 of the information terminal 50 determines whether or not the operator has performed any one of an operation for apparatus change (selection of the “first target apparatus change” button 330 or the “second target apparatus change” button 335), an operation for sensor change (selection of the “first sensor change” button 340 or the “second sensor change” button 345), and an operation for period change to the previous year or the next year (selection of the “display period change” button 350 or 355) (step S112).

In the case where any one of the operation for apparatus change, the operation for sensor change, and the operation for period change to the previous year or the next year has been performed (S112: Yes), the next processing is performed in step S109.

The arithmetic processing unit 51 of the information terminal 50 requests the server 40 to transmit data representing measured values for a year corresponding to an operation by the operator. In response to the transmission request, the arithmetic processing unit 51 receives from the server 40 the data representing the measured values for the year corresponding to the transmission request. Then, based on the received data representing the measured values for the year, the arithmetic processing unit 51 displays on the display unit 53 the first display screen 100 on which one or both of the first graphs 310 and 315 have been updated.

In the case where the operation for apparatus change is performed for the first target apparatus, the transmission request is a request to transmit data representing measured values for the year indicated in the first graph 310, the measured values being obtained by a sensor at an apparatus different from that indicated in the first graph 310 at the current point in time. In the case where the operation for apparatus change is performed for the second target apparatus, the transmission request is a request to transmit data representing measured values for the year indicated in the first graph 315, the measured values being obtained by a sensor at an apparatus different from that indicated in the first graph 315 at the current point in time. Furthermore, in the case where the operation for sensor change is performed for the first sensor, the transmission request is a request to transmit data representing measured values for the year indicated in the first graph 310, the measured values being obtained by a different sensor at the same apparatus as that indicated in the first graph 310 at the current point in time. Furthermore, in the case where the operation for sensor change is performed for the second sensor, the transmission request is a request to transmit data representing measured values for the year indicated in the first graph 315, the measured values being obtained by a different sensor at the same apparatus as that indicated in the first graph 315 at the current point in time. Furthermore, in the case where the operation for period change to the previous year is performed, the transmission request is a request to transmit data representing measured values for the year previous to the year indicated in the first graphs 310 and 315, the measured values being obtained by the same sensors as those indicated in the first graphs 310 and 315 at the current point in time. Furthermore, in the case where the operation for period change to the next year is performed, the transmission request is a request to transmit data representing measured values for the year next to the year indicated in the first graphs 310 and 315, the measured values being obtained by the same sensors as those indicated in of the first graphs 310 and 315 at the current point in time.

In the case where none of the operation for apparatus change, the operation for sensor change, and the operation for period change to the previous year or the next year has been performed (S112: No), the arithmetic processing unit 51 of the information terminal 50 determines whether or not the operator has performed selection of a target to be indicated in the first graph 110 on the first display screen 100 (selection of the “first target” button 370 or the “second target” button 375) (step S113).

In the case where target selection has been performed (S113: Yes), the next processing is performed in step S106. In the case where the operator has selected the “first target” button 370, the arithmetic processing unit 51 of the information terminal 50 displays on the display unit 53 the first display screen on which the first measured values of the first graph 310 are indicated as the first measured values of the first graph 110. Furthermore, in the case where the operator has selected the “second target” button 375, the arithmetic processing unit 51 of the information terminal 50 displays on the display unit 53 the first display screen on which the second measured values of the first graph 315 are indicated as the first measured values of the first graph 110.

In the case where target selection has not been performed (S113: No), the arithmetic processing unit 51 of the information terminal 50 determines whether or not the operator has performed a selection operation for a region of the first graph 310 or 315 (S114). In the case where no selection operation has been performed for a region of the first graph 310 or 315 (step S114: No), the process returns to the processing of step S110.

In the case where a selection operation has been performed for a region of the first graph 310 or 315 (S114: Yes), the next processing is performed in step S109.

In the case where a selection operation is performed for a region of the first graph 310, the processing described below is performed.

The arithmetic processing unit 51 of the information terminal 50 requests the server 40 to transmit data representing measured values for the date specified by the operator, the measured values being obtained by sensors (three sensors in the example of the second display screen in FIG. 5) different from that indicated in the first graph 310 at the current point in time. The date specified by the operator corresponds to the region for which the operator has performed the selection operation in the first graph 310. In response to the transmission request, the arithmetic processing unit 51 receives from the server 40 the data representing the measured values for the date specified by the operator, the measured values being obtained by the different sensors (three sensors) corresponding to the transmission request. Then, the arithmetic processing unit 51 displays the second display screen. The second graph 210 on the second display screen is displayed based on the data representing the measured values for the date specified by the operator among the data used for the indication of the first measured values of the first graph 310. Furthermore, the second graphs 220a, 220b, and 220c are displayed based on the data representing the measured values for the date specified by the operator, the measured values being obtained by the three sensors received as a response to the transmission request.

In the case where a selection operation is performed for a region of the first graph 315, the processing described below is performed.

The arithmetic processing unit 51 of the information terminal 50 requests the server 40 to transmit data representing measured values for the date specified by the operator, the measured values being obtained by sensors (three sensors in the example of the second display screen in FIG. 5) different from that indicated in the first graph 315 at the current point in time. The date specified by the operator corresponds to the region for which the operator has performed the selection operation in the first graph 315. In response to the transmission request, the arithmetic processing unit 51 receives from the server 40 the data representing the measured values for the date specified by the operator, the measured values being obtained by the different sensors (three sensors) corresponding to the transmission request. Then, the arithmetic processing unit 51 displays the second display screen. The second graph 210 on the second display screen is displayed based on the data representing the measured values for the date specified by the operator among the data used for the indication of the second measured values of the first graph 315. Furthermore, the second graphs 220a, 220b, and 220c are displayed based on the data representing the measured values for the date specified by the operator, the measured values being obtained by the three sensors received as a response to the transmission request.

### (Transition of Display Screen)

Hereinafter, screen transition between the first display screen, the second display screen, and the third display screen will be described.

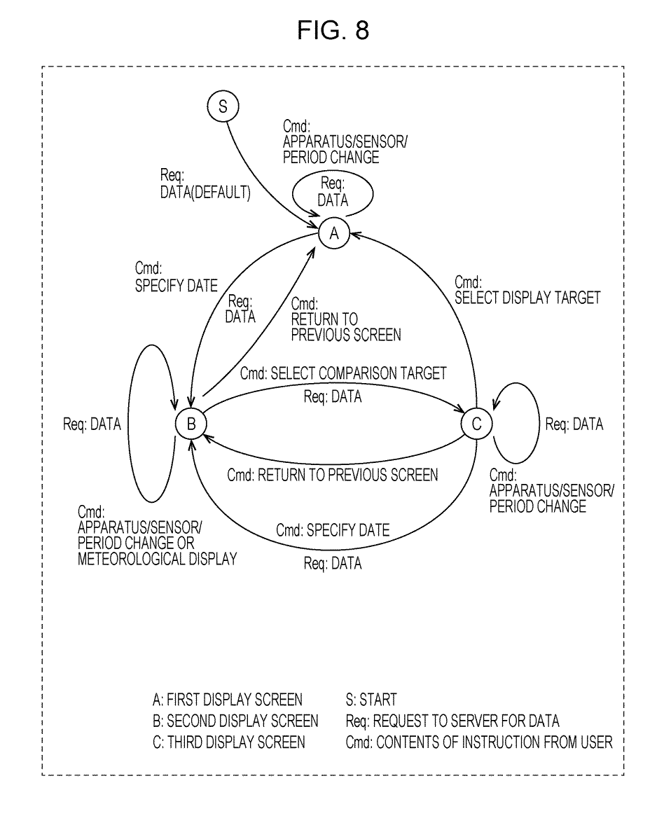

FIG. 8 is a transition diagram illustrating transition of display screens displayed on the display of the display unit 53 of the information terminal 50 in FIG. 2. In FIG. 8, states where the first display screen, the second display screen, and the third display screen are displayed are referred to as states A, B, and C, respectively, and the initial state is represented by S. The initial state S is a convenient state immediately after the system is activated or the like, in particular, before the first display screen or the like is displayed. Information that the information terminal 50 acquires from the server 40 has been described above with reference to FIG. 7, and therefore, explanation for such information will be omitted in the explanation for transition of screens.

In the initial state S, in accordance with an operation by an operator to display the first display screen, the first display screen 100 is displayed (transition from the initial state S to the state A).

On the first display screen 100, the operator selects the first target apparatus change” button 130 (apparatus change), the “first sensor change” button 140 (sensor change), or the “display period change” button 150a or 150b (period change). In this case, on the display unit 53 of the information terminal 50, the first display screen 100 on which the details of measured values of the first graph 110 have been updated is displayed (transition from the state A to the state A).

On the first display screen 100, the operator selects a region of the first graph 110 (date specification). Accordingly, the display contents of the display unit 53 of the information terminal 50 are switched from the first display screen 100 to the second display screen 200 (transition from the state A to the state B).

On the second display screen 200, the operator selects the “previous screen” button 290. Accordingly, the display contents of the display unit 53 of the information terminal 50 are switched from the second display screen 200 to the first display screen 100 (transition from the state B to the state A).

On the second display screen 200, the operator selects the “second target apparatus change” button 250 (apparatus change), the “second sensor change” button 260 (sensor change), the “display period change” button 280a or 280b (period change), or the “meteorological bureau” button 270 (meteorology change). Accordingly, on the display unit 53 of the information terminal 50, the second display screen 200 on which the details of measured values of the second graphs 220a, 220b, and 220c have been updated is displayed (transition from the state B to the state B).

On the second display screen 200, the operator selects any one of the second graphs 220a, 220b, and 220c (selection of a comparison target). Accordingly, the display contents of the display unit 53 of the information terminal 50 are switched from the second display screen 200 to the third display screen 300 (transition from the state B to the state C).

On the third display screen, the operator selects the “previous screen” button 360. Accordingly, the display contents of the display unit 53 of the information terminal 50 returns from the third display screen 300 to the second display screen 200 (transition from the state C to the state B).

On the third display screen 300, the operator selects the first target apparatus change” button 330 (apparatus change), the “first sensor change” button 340 (sensor change), the “second target apparatus change” button 335 (apparatus change), the “second sensor change” button 345 (sensor change), or the “display period change” button 350 or 355 (period change). Accordingly, on the display unit 53 of the information terminal 50, the third display screen 300 on which the contents of measured values of one or both of the first graphs 310 and 315 have been updated is displayed (transition from the state C to the state C).

On the third display screen 300, the operator selects a region of the first graph 310 or 315 (date specification). Accordingly, the display contents of the display unit 53 of the information terminal 50 are switched from the third display screen 300 to the second display screen 200 (transition from the state C to the state B).

On the third display screen 300, the operator selects any one of the “first target” button 370 and the “second target” button 375. Accordingly, the display contents of the display unit 53 of the information terminal 50 are switched from the third display screen 300 to the first display screen 100 (transition from the state C to the state A).

### <<Supplementary Explanation (Part 1)>>

The present disclosure is not limited to the above-described embodiments. The present disclosure may be implemented in a variety of forms, such as those described below, for achieving an object of the present disclosure or other objects related or associated thereto. For example, the following modifications are possible.

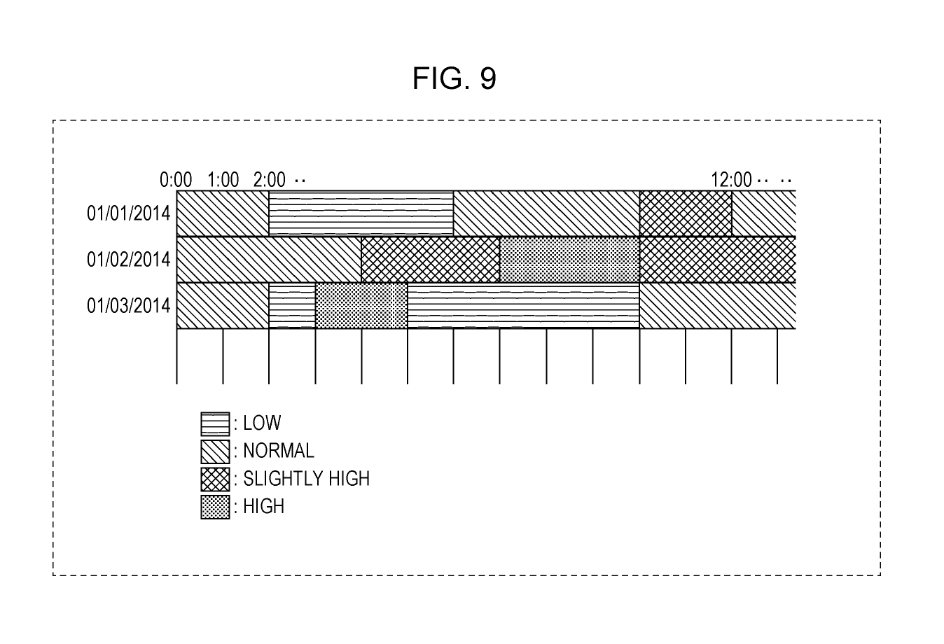

(1) In an embodiment described above, sizes of measured values are represented by different thicknesses of the same color or different display colors in the first graph 110. However, the present disclosure is not limited to this. For example, as represented by a form of indication illustrated in FIG. 9, 10, or 11, measured values of the first graph 110 may be represented such that changes in the size of measured values are explicitly indicated.

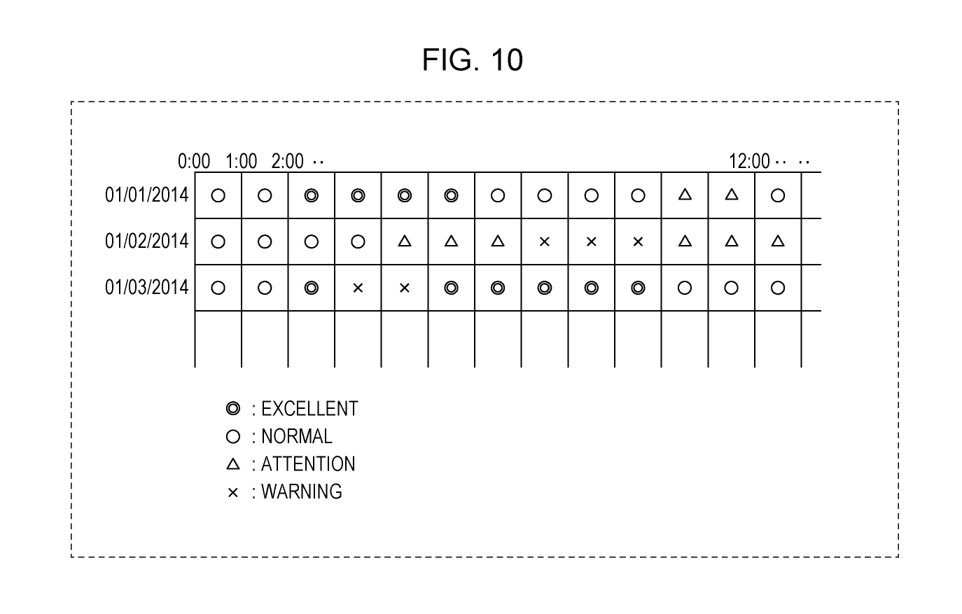

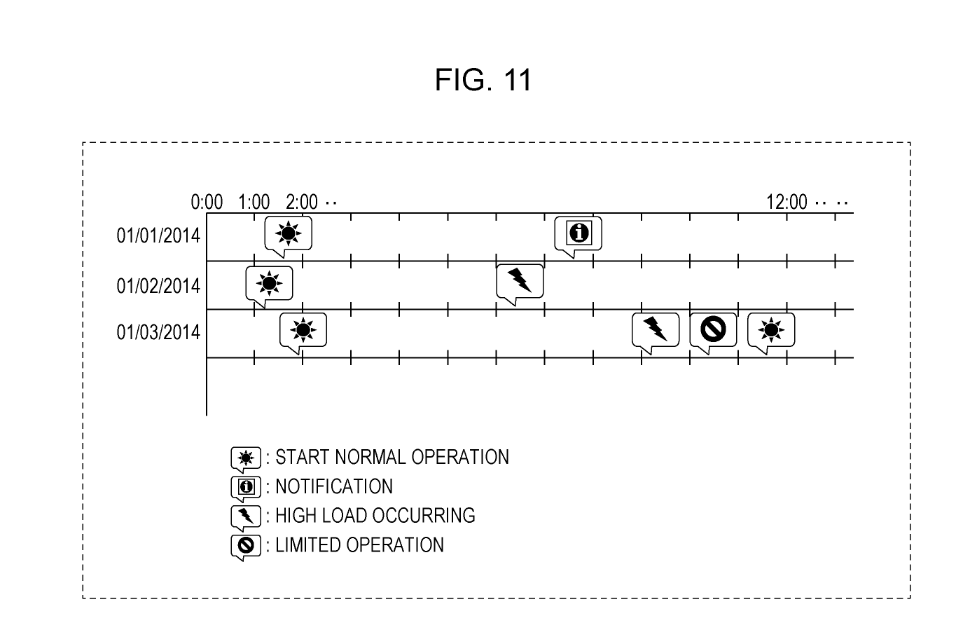

In the example of FIG. 9, sizes of measured values are represented by different hatching styles in the first graph 110. In the example of FIG. 10, sizes of measured values are represented by different marks in the first graph 110. In the example of FIG. 11, sizes of measured values are represented by different icons in the first graph 110.

(2) In an embodiment described above, display is switched from the first display screen 100 to the third display screen 300 via the second display screen 200. However, the present disclosure is not limited to this. Display may be switched directly from the first display screen 100 to the third display screen 300. For example, the following modifications are possible. An operation region for which an instruction to display a plurality of first graphs is given by an operator is arranged on the first display screen 100. In the case where the operator has performed an operation for the operation region, the arithmetic processing unit 51 of the information terminal 50 requests the server 40 to transmit data representing measured values for a year indicated in the first graph 110 obtained by a different sensor. In response to the request, the arithmetic processing unit 51 of the information terminal 50 receives from the server 40 the data representing the measured values for the year for which the transmission request has been transmitted. Then, the arithmetic processing unit 51 displays on the display unit 53 the third display screen 300 on which the first measured values of the first graph 110 are indicated as the first measured values of the first graph 310 and the received measured values are indicated as the second measured values of the first graph 315.

(3) In an embodiment described above, on the first display screen 100, an operator is not able to perform an operation for issuing an instruction to display meteorological information of the location of the facility. However, the present disclosure is not limited to this. On the first display screen 100, an operator may be able to perform an operation for issuing an instruction to display meteorological information of the location of the facility.

For example, a region representing measured values for a day of the first graph 110 is divided into a region for an “operation for issuing an instruction to indicate measured values obtained by a different sensor” and a region for an “operation for issuing an instruction to display meteorological information”. Then, in the case where the operator has performed a selection operation for the region for the “operation for issuing an instruction to indicate measured values obtained by a different sensor”, the measured values obtained by the different sensor for the date corresponding to the region for which the selection operation has been performed are indicated in the second graphs 220a, 220b, and 220c on the second display screen 200. In contrast, in the case where the operator has performed a selection operation for the region for the “operation for issuing an instruction to display meteorological information”, the arithmetic processing unit 51 of the information terminal 50 requests the server 40 to transmit data representing meteorological information of the location of the facility for the date corresponding to the region for which the selection operation has been performed. In response to the transmission request, the arithmetic processing unit 51 of the information terminal 50 receives from the server 40 the data representing the meteorological information of the location of the facility for the date for which the transmission request has been transmitted. Then, the arithmetic processing unit 51 displays the received meteorological information of the location of the facility in the second graphs 220a, 220b, and 220c on the second display screen 200.

Furthermore, a “meteorological bureau” button is provided on the first display screen 100. In the case where a selection operation is performed by the operator for the “meteorological bureau” button, the arithmetic processing unit 51 of the information terminal 50 requests the server 40 to transmit data representing meteorological information of the location of the facility for the year indicated in the first graph 110. In response to the transmission request, the arithmetic processing unit 51 of the information terminal 50 receives from the server 40 the data representing the meteorological information of the location of the facility for the year for which the transmission request has been transmitted. Then, the arithmetic processing unit 51 displays the received meteorological information of the location of the facility in the first graph 315 of the third display screen 300.

(4) In an embodiment described above, on the second display screen 200, an operator is not able to perform an operation for issuing an instruction to indicate measured values for a year obtained by the second sensor of the second graph 220a or the like in the first graph 110 on the first display screen 100. However, the present disclosure is not limited to this. On the second display screen 200, the operator may be able to perform an operation for issuing an instruction to indicate the measured values for the year obtained by the second sensor of the second graph 220a or the like in the first graph 110 on the first display screen 100.

In this case, switching from the second display screen 200 to the first display screen 100 or switching from the second display screen 200 to the third display screen 300 is performed. For example, an indicator which allows an operator to select which screen the display is to be switched to is provided. The operator specifies which screen the display is to be switched to using the indicator, and then selects an region of any of the second graph 220a, 220b, or 220c.

(5) In an embodiment described above, for apparatus change or sensor change, apparatuses provided at the facility may be sequentially selected for change or sensors may be sequentially selected for change. Furthermore, the order in which other apparatuses are indicated may be determined for each apparatus or the order in which other apparatuses are indicated may be determined for each sensor. In changing an apparatus or changing a sensor, selection may be made in accordance with the determined order.

(6) A first sensor, a second sensor, and the like used in an embodiment described above will be described below.

As the relationship between first measured values and second measured values which are indicated at the same time, measured values obtained by a plurality of sensors provided at a specific target apparatus (first measured values and second measured values are obtained by different sensors at the same apparatus) may be considered. The first and second measured values may be, for example, measured values of the suction temperature of an air-conditioning apparatus and measured values of the air volume of the air-conditioning apparatus, measured values of the internal temperature of a cooling case and measured values of the setting temperature of the cooling case, measured values of the illuminance of a lighting apparatus and measured values of the power consumption of the lighting apparatus, and the like.

Furthermore, measured values obtained by sensors of a specific type provided at a plurality of apparatuses of the same type (first measured values and second measured values are obtained by sensors of the same type of different apparatuses) may be considered. The first and second measured values may be, for example, measured values of the suction temperature of different air-conditioning apparatuses, counter values of opening and closing pulses at different doors, and the like.

Furthermore, measured values obtained by sensors of a specific type provided at apparatuses installed adjacent to each other (first measured values and second measured values are obtained by sensors arranged adjacent to each other) may be considered. The first and second measured values may be, for example, counter values of opening and closing pulses at a door and measured values obtained by an adjacent temperature/humidity sensor (within a range affected by air flow from door/to door), measured values of the power consumption of a lighting apparatus and measured values of the power consumption of an air-conditioning apparatus in the same area (within an area which is affected by lighting), and the like.

Furthermore, measured values obtained by a plurality of sensors for which a physical causal relationship are assumed (first measured values obtained by the first sensor and second measured values obtained by the second sensor are obtained by sensors having a physical causal relationship/correlation) may be considered. The first and second measured values may be, for example, measured values of the air volume of an air-conditioning apparatus and measured values of the internal temperature of a cooling case in an area which is affected by the air, measured values obtained by a temperature/humidity sensor provided inside a building and measured values of the sunshine duration based on meteorological data, and the like.

Furthermore, measured values obtained by a plurality of sensors provided at a plurality of target apparatuses having a connected relationship in terms of equipment (the first measured values and the second measured values are obtained by sensors at apparatuses having a connected relationship in terms of equipment) may be considered. The first measured and second measured values may be, for example, measured values of the blowing temperature of an air-conditioning apparatus and measured values of the refrigerant pressure at a corresponding refrigerating apparatus (outdoor unit), measured values of the suction temperature in the refrigerating apparatus (outdoor unit) and measured values of the amount of water supply in a connected water supply apparatus, and the like.

In the case where a large number of sensors have a causal relationship or correlation, a range of sensors may be limited by numerical values. For example, (a plurality of) second measured values may be selected by reducing the number of measured values to be indicated at the same time on the second display screen, according to what percent of the volume of air blown from a ventilation port or a blowing port reaches (or how large radius) a sensor, what percent of necessary designed illuminance the illuminance of lighting includes, what is the radius from a door, a humidity sensor, or a cooling case, or the like.

Furthermore, a correlation coefficient of measured values (first measured values) obtained by a target sensor and measured values (may be second measured values) obtained by a different sensor may be obtained. Measured values obtained by the different sensor with a correlation coefficient within, for example, a range from −1 to −0.5 or a range from 0.5 to 1 may be selected as (a plurality of) second measured values.

The contents including part of the above contents will further be described below.

For example, the first sensor is a wattmeter of an air-conditioning apparatus, and the first measured values are power consumption of the air-conditioning apparatus or instantaneous power consumption of the air-conditioning apparatus. For example, the first sensor is a discharge sensor of an air-conditioning apparatus, and the first measured values are discharge temperature of the air-conditioning apparatus. For example, the first sensor is an air volume sensor of an air-conditioning apparatus, and the first measured values are the air volume of the air-conditioning apparatus.

For example, in the case where the first target apparatus is an air-conditioning apparatus, the second measured values are environmental information within a range in which the air speed of air blown from the air-conditioning apparatus is equal to or higher than a predetermined threshold. For example, the second sensor is a wattmeter of a lighting apparatus, and the second measured values are power consumption of the lighting apparatus or instantaneous power consumption of the lighting apparatus. For example, the second sensor is an illuminance meter of a lighting apparatus, and the second measured values are information indicating the brightness of the lighting apparatus. When the first target apparatus is a lighting apparatus, the second measured values are environmental information within a range in which the output amount of the lighting apparatus is equal to or more than a predetermined threshold. In the case where the second sensor is an opening and closing sensor for a door, the second measured values are information indicating the number of opening and closing times of the door. A sensor measuring a 24-hour operating specific apparatus, such as a refrigerating apparatus, may be excluded from the second sensor.

(7) The information terminal explained above in an embodiment, the supplementary explanation (part 1), or the like may be implemented by a large scale integration (LSI), which is an integrated circuit. In this case, component elements may be individually formed as a single chip or a part or all of the component elements may be formed as a single chip. In the above description, the information terminal has been referred to as an LSI. However, depending on the degree of integration, the information terminal may be referred to as an integrated circuit (IC), a system LSI, a super LSI, or an ultra LSI. Furthermore, circuit integration is not limited to LSI. Circuit integration may be implemented by a dedicated circuit or a general-purpose processor. A field programmable gate array (FPGA) or a reconfigurable processor in which connection of circuit cells inside an LSI or reconfiguration of setting is possible may be used. Obviously, if a circuit integration technology which will be replaced with LSIs will become available by advances in a semiconductor technology or a developed different technology, integration of functional blocks may be achieved using the technology.

(8) At least part of the procedure of an operation of the information terminal described above in an embodiment, the supplementary explanation (part 1), or the like may be described in a program, and for example, a central processing unit (CPU) may read the program stored in a memory and execute the read program. Furthermore, the program may be stored in a recording medium and distributed.

(9) The contents described above in an embodiment or the supplementary explanation (part 1) may be combined together in an appropriate manner.

### <<Supplementary Explanation (Part 2)>>

An integrated control method, an integrated control apparatus, a non-transitory computer-readable recording medium, and an information terminal according to an embodiment and the supplementary explanation (part 1) will be summarized below.

According to an aspect of the present disclosure, a method for an information terminal, includes: upon receiving a request to indicate first measured values for a plurality of days obtained by a first measuring device and associated with the operation of an energy-consuming apparatus installed at a facility, acquiring data of the first measured values for the plurality of days is acquired from the storing device; and displaying on a display of the information terminal a first display screen on which sizes of the first measured values are indicated, based on the data of the first measured values for the plurality of days, by different forms of indication in a first graph where a first axis represents dates and a second axis represents hours.

According to an aspect of the present disclosure, in a non-transitory computer-readable recording medium storing a program executed in an information terminal, the program causing the information terminal to execute: upon receiving a request to indicate first measured values for a plurality of days obtained by a first measuring device and associated with the operation of an energy-consuming apparatus installed at a facility, acquiring data of the first measured values for the plurality of days from the storing device; and displaying on a display of the information terminal a first display screen on which sizes of the first measured values are indicated, based on the data of the first measured values for the plurality of days, by different forms of indication in a first graph where a first axis represents dates and a second axis represents hours.

According to an aspect of the present disclosure, an information terminal includes: an acquisition unit that acquires, upon receiving a request to indicate first measured values for a plurality of days obtained by a first measuring device and associated with the operation of an energy-consuming apparatus installed at a facility, data of the first measured values for the plurality of days from a storing device; and a display controller that displays on a display of the information terminal a first display screen on which sizes of the first measured values are indicated, based on the data of the first measured values for the plurality of days, by different forms of indication in a first graph where a first axis represents dates and a second axis represents hours.

According to the above aspects, the first graph indicates, with a two-dimensional graph in which each of the first axis and the second axis is a time-scale axis, sizes of measured values, as a third element, are represented by different thicknesses. Therefore, even with the two-dimensional graph, the three elements (dates, hours, and measured values) may be indicated in a single first graph. Accordingly, macro-evaluation of measured values for a plurality of days and micro-evaluation of measured values for a shorter period of time may be achieved easily.

According to a second aspect of the present disclosure, the method for the information terminal according to the first embodiment, may include: upon receiving a request to indicate the first measured values and second measured values obtained by a second measuring device on a specific date among the plurality of days, acquiring data of the second measured values on the specific date from the storing device; and displaying on the display of the information terminal a second display screen on which the first measured values and the second measured values are indicated, based on the data of the first measured values and the data of the second measured values on the specific date, in a second graph where a third axis represents hours of the specific date and a fourth axis represents the first measured values and the second measured values.

According to this aspect, micro-evaluation of measured values may be achieved by referring to measured values obtained at the same period of time by different measuring devices.

According to a third aspect of the present disclosure, in the method for the information terminal according to the second aspect, the request to indicate the first measured values and the second measured values on the specific date may be made when an operator of the information terminal selects a region in the first graph that corresponds to the specific date.

According to this aspect, the operator may easily specify a specific date to be indicated in the second graph.

According to a fourth aspect of the present disclosure, the method for the information terminal according to the first aspect, may include: upon receiving a request to indicate the first measured values and second measured values obtained by a second measuring device for the plurality of days, acquiring data of the second measured values for the plurality of days from the storing device; and displaying on the display of the information terminal a third display screen on which sizes of the first measured values and sizes of the second measured values are indicated, based on the data of the first measured values and the data of the second measured values for the plurality of days, by different forms of indication in the first graph.

According to this aspect, macro-evaluation of measured values for a plurality of days may be achieved by referring to measured values obtained at the same period of time by different measuring devices.

According to a fifth aspect of the present disclosure, the method for the information terminal according to the second or third aspect, may include: when a region in the second graph in which the second measured values are indicated is selected by an operator of the information terminal, acquiring the data of the second measured values for the plurality of days from the storing device; and displaying on the display of the information terminal a third display screen on which sizes of the first measured values and sizes of the second measured values are indicated, based on the data of the first measured values and the data of the second measured values for the plurality of days, by different forms of indication in the first graph.

According to this aspect, macro-evaluation of measured values for a plurality of days may be achieved by referring to measured values obtained at the same period of time by different measuring devices.

According to the sixth aspect of the present disclosure, the control method for the information terminal according to the second, third, or fifth aspect, may include: upon receiving a request to indicate meteorological information of a location of the facility on the specific date, acquiring data of the meteorological information of the location of the facility on the specific date from a storing device that stores data of the meteorological information; and displaying on the display of the information terminal the second display screen on which the meteorological information of the location of the facility is indicated, based on the data of the meteorological information of the location of the facility, in the second graph where the third axis represents hours of the specific date and the fourth axis represents the meteorological information may be displayed on the display.

According to this aspect, evaluation of measured values may be achieved by referring to meteorological information of the location of a facility obtained at the same period of time.

According to a seventh aspect of the present disclosure, the control method for the information terminal according to the first or fourth aspect, may include: upon receiving a request to indicate meteorological information of a location of the facility on a specific date among the plurality of days, acquiring data of the meteorological information of the location of the facility on the specific date from a storing device that stores data of the meteorological information; and displaying on the display of the information terminal a fourth display screen on which the first measured values and the meteorological information of the location of the facility are indicated, based on the data of the first measured values and the data of the meteorological information of the location of the facility on the specific date, in a fourth graph where a fifth axis represents hours of the specific date and a sixth axis represents the first measured values and the meteorological information.

According to this aspect, evaluation of measured values may be achieved by referring to meteorological information of the location of a facility obtained at the same period of time.

According to an eighth aspect of the present disclosure, in the method for the information terminal according to the seventh aspect, the request to indicate the meteorological information of the location of the facility on the specific date among the plurality of days may be made when an operator of the information terminal selects a region in the first graph included in the first display screen.

According to this aspect, the operator may easily make a request for meteorological information.

According to a ninth aspect of the present disclosure, in the method for the information terminal according to any one of the first to eighth aspects, the plurality of days may be one year.

According to a tenth aspect of the present disclosure, in the method for the information terminal according to any one of the first to eighth aspects, the plurality of days may be one month.

According to an eleventh aspect of the present disclosure, in the method for the information terminal according to the second, third, fifth, or sixth aspect, the second measured values may be a plurality of types of values, and the second graph may include a plurality of graphs which are associated with the plurality of types of second measured values.

According to a twelfth aspect of the present disclosure, in the method for the information terminal according to any one of the first to eleventh aspects, the first measuring device may be a wattmeter at an air-conditioning apparatus, and the first measured values may be power consumption of the air-conditioning apparatus or instantaneous power consumption of the air-conditioning apparatus.

According to a thirteenth aspect of the present disclosure, in the method for the information terminal according to any one of the first to eleventh aspects, the first measuring device may be a discharge sensor at an air-conditioning apparatus, and the first measured values may be discharge temperature of the air-conditioning apparatus.

According to a fourteenth aspect of the present disclosure, in the method for the information terminal according to any one of the first to eleventh aspects, the first measuring device may be an air volume sensor at an air-conditioning apparatus, and the first measured values may be air volume of the air-conditioning apparatus.

According to a fifteenth aspect of the present disclosure, in the method for the information terminal according to the twelfth to fourteenth aspects, when the energy-consuming apparatus is an air-conditioning apparatus, the second measured values may include environmental information within a range where an air speed of air blown from the air-conditioning apparatus is equal to or higher than a predetermined threshold.

According to a sixteenth aspect of the present disclosure, in the method for the information terminal according to the twelfth to fourteenth aspects, the second measuring device may be a wattmeter of a lighting apparatus, and the second measured values may be power consumption of the lighting apparatus or instantaneous power consumption of the lighting apparatus.

According to a seventeenth aspect of the present disclosure, in the method for the information terminal according to the twelfth to fourteenth aspects, the second measuring device may be an illuminance meter of a lighting apparatus, and the second measured values may be information indicating a brightness of the lighting apparatus.

According to an eighteenth aspect of the present disclosure, in the method for the information terminal according to the twelfth to fourteenth aspects, when the energy-consuming apparatus is a lighting apparatus, the second measured values may include environmental information within a range in which an output amount of the lighting apparatus is equal to or more than a predetermined threshold.

According to a nineteenth aspect of the present disclosure, in the method for the information terminal according to the twelfth to fourteenth aspects, when the second measuring device is an opening and closing sensor for a door, the second measured values may be information indicating the number of opening and closing times of the door.

According to a twentieth aspect of the present disclosure, in the method for the information terminal according to the second, third, fifth, and sixth aspects, the second measured values may be correlated with the first measured values, and a correlation function of the first measured values and the second measured values may be within a range from −1 to −0.5 or a range from 0.5 to 1.

According to a twenty-first aspect of the present disclosure, in the method for the information terminal according to the second, third, fifth, and sixth aspects, a 24-hour operating specific apparatus may be excluded from the second measuring device.

According to a twenty-second aspect of the present disclosure, in the method for the information terminal according to the twenty-first aspect, the specific apparatus may include a refrigerating apparatus.

The present disclosure may be used for display control of an information terminal.

What is claimed is:

1. A method comprising:
upon receiving a request to indicate first measured values for a plurality of days obtained by a first measuring device and associated with the operation of an energy-consuming apparatus installed at a facility, acquiring data of the first measured values for the plurality of days from a storing device; and
displaying on a display of the information terminal a first display screen on which sizes of the first measured values are indicated, based on the data of the first measured values for the plurality of days, by different forms of indication in a first graph where a first axis represents dates and a second axis represents hours.

2. The method according to claim 1, comprising:
upon receiving a request to indicate the first measured values and second measured values obtained by a second measuring device on a specific date among the plurality of days, acquiring data of the second measured values on the specific date from the storing device, and
displaying on the display of the information terminal a second display screen on which the first measured values and the second measured values are indicated, based on the data of the first measured values and the data of the second measured values on the specific date, in a second graph where a third axis represents hours of the specific date and a fourth axis represents the first measured values and the second measured values.

3. The method according to claim 2, wherein the request to indicate the first measured values and the second measured values on the specific date is made when an operator of the information terminal selects a region in the first graph that corresponds to the specific date.

4. The method according to claim 1, comprising:
upon receiving a request to indicate the first measured values and second measured values obtained by a second measuring device for the plurality of days, acquiring data of the second measured values for the plurality of days from the storing device, and
displaying on the display of the information terminal a third display screen on which sizes of the first measured values and sizes of the second measured values are indicated, based on the data of the first measured values and the data of the second measured values for the plurality of days, by different forms of indication in the first graph.

5. The method according to claim 2, comprising:
when a region in the second graph in which the second measured values are indicated is selected by an operator of the information terminal, acquiring the data of the second measured values for the plurality of days from the storing device, and
displaying on the display of the information terminal a third display screen on which sizes of the first measured values and sizes of the second measured values are indicated, based on the data of the first measured values and the data of the second measured values for the plurality of days, by different forms of indication in the first graph.

6. The method according to claim 2, comprising:
upon receiving a request to indicate meteorological information of a location of the facility on the specific date, acquiring data of the meteorological information of the location of the facility on the specific date from a storing device that stores data of the meteorological information, and
displaying on the display of the information terminal the second display screen on which the meteorological information of the location of the facility is indicated, based on the data of the meteorological information of the location of the facility, in the second graph where the third axis represents hours of the specific date and the fourth axis represents the meteorological information.

7. The method according to claim 1, comprising:
upon receiving a request to indicate meteorological information of a location of the facility on a specific date among the plurality of days, acquiring data of the meteorological information of the location of the facility on the specific date from a storing device that stores data of the meteorological information, and
displaying on the display of the information terminal a fourth display screen on which the first measured values and the meteorological information of the location of the facility are indicated, based on the data of the first measured values and the data of the meteorological information of the location of the facility on the specific date, in a fourth graph where a fifth axis represents hours of the specific date and a sixth axis represents the first measured values and the meteorological information.

8. The control method for the information terminal according to claim 7, wherein the request to indicate the meteorological information of the location of the facility on the specific date among the plurality of days is made when an operator of the information terminal selects a region in the first graph included in the first display screen.

9. The control method for the information terminal according to claim 2,
wherein the second measured values are a plurality of types of values, and
wherein the second graph includes a plurality of graphs which are associated with the plurality of types of second measured values.

10. The control method for the information terminal according to claim 1, wherein the first measuring device is a wattmeter at an air-conditioning apparatus, and the first measured values are power consumption of the air-conditioning apparatus or instantaneous power consumption of the air-conditioning apparatus.

11. The control method for the information terminal according to claim 1, wherein the first measuring device is a discharge sensor at an air-conditioning apparatus, and the first measured values are discharge temperature of the air-conditioning apparatus.

12. The control method for the information terminal according to claim 1, wherein the first measuring device is an air volume sensor at an air-conditioning apparatus, and the first measured values are air volume of the air-conditioning apparatus.

13. The control method for the information terminal according to claim 10, wherein when the energy-consuming apparatus is an air-conditioning apparatus, the second measured values include environmental information within a range where an air speed of air blown from the air-conditioning apparatus is equal to or higher than a predetermined threshold.

14. The control method for the information terminal according to claim 10, wherein the second measuring device is a wattmeter of a lighting apparatus, and the second measured values are power consumption of the lighting apparatus or instantaneous power consumption of the lighting apparatus.

15. The control method for the information terminal according to claim 10, wherein the second measuring device is an illuminance meter of a lighting apparatus, and the second measured values are information indicating a brightness of the lighting apparatus.

16. The control method for the information terminal according to claim 10, wherein when the energy-consuming apparatus is a lighting apparatus, the second measured values include environmental information within a range in which an output amount of the lighting apparatus is equal to or more than a predetermined threshold.

17. The control method for the information terminal according to claim 10, wherein when the second measuring device is an opening and closing sensor for a door, the second measured values are information indicating the number of opening and closing times of the door.

18. The control method for the information terminal according to claim 2, wherein a 24-hour operating specific apparatus is excluded from the second measuring device.

19. The control method for the information terminal according to claim 18, wherein the specific apparatus includes a refrigerating apparatus.

20. An information terminal comprising:
an acquisition unit that acquires, upon receiving a request to indicate first measured values for a plurality of days obtained by a first measuring device and associated with the operation of an energy-consuming apparatus installed at a facility, data of the first measured values for the plurality of days from a storing device; and
a display controller that displays on a display of the information terminal a first display screen on which sizes of the first measured values are indicated, based on the data of the first measured values for the plurality of days, by different forms of indication in a first graph where a first axis represents dates and a second axis represents hours.
